(19) United States
(12) Patent Application Publication
(10) Pub. No.: US 2024/0258208 A1
(43) Pub. Date: Aug. 1, 2024

(54) SEMICONDUCTOR DEVICE

(71) Applicant: ROHM CO., LTD., Kyoto (JP)

(72) Inventors: Hajime OKUDA, Kyoto (JP); Adrian JOITA, Kyoto (JP)

(73) Assignee: ROHM CO., LTD., Kyoto (JP)

(21) Appl. No.: 18/616,483

(22) Filed: Mar. 26, 2024

Related U.S. Application Data
(63) Continuation of application No. PCT/JP2022/031334, filed on Aug. 19, 2022.

(30) Foreign Application Priority Data
Nov. 8, 2021 (JP) 2021-181840

(51) Int. Cl. H01L 23/495; H01L 23/00; H01L 25/065

(52) U.S. Cl. CPC H01L 23/49527; H01L 23/49575; H01L 24/08; H01L 24/48; H01L 25/0652; H01L 2224/08145; H01L 2224/08245; H01L 2224/48132; H01L 2224/48177; H01L 2924/0665; H01L 2924/1306

(57) ABSTRACT

A semiconductor device includes a semiconductor chip including a first principal surface in which an element region is formed and a peripheral end surface surrounding the first principal surface and an inspection wiring formed along the peripheral end surface on a side of the first principal surface of the semiconductor chip and that surrounds the element region, and, the inspection wiring includes a plurality of internal wiring portions that are formed at a surficial portion of the first principal surface of the semiconductor chip and that are arrayed at a distance from each other along the peripheral end surface of the semiconductor chip and a extending wiring portion that is formed on the first principal surface of the semiconductor chip and that is provided between the internal wiring portions adjoining each other, and the internal wiring portion and the extending wiring portion are alternately arrayed along the peripheral end surface.

### CROSS-REFERENCE TO RELATED APPLICATIONS

This application is a bypass continuation of International Patent Application No. PCT/JP2022/031334, filed on Aug. 19, 2022, which corresponds to Japanese Patent Application No. 2021-181840 filed in the Japan Patent Office on Nov. 8, 2021, the entire disclosure of each are incorporated herein by reference.

### TECHNICAL FIELD

The present disclosure relates to a semiconductor device.

### BACKGROUND

For example, Patent Literature 1 (Japanese Patent Application Publication No. 2005-277338) discloses a semiconductor wafer composed of a plurality of scribe regions that extend in two mutually-different directions at an equal interval therebetween and a chip region surrounded by the scribe region. A pad connected to an internal circuit or to an internal wiring is arrayed in the chip region, and an inspection wiring formed by use of a wiring layer that is the same layer as the pad is further provided over substantially the entire perimeter of the chip region near the scribe region located outside the pad.

### BRIEF DESCRIPTION OF THE DRAWINGS

FIG. 1 is a schematic plan view of a semiconductor device according to a preferred embodiment of the present disclosure.

FIG. 2 is a schematic cross-sectional view of the semiconductor device.

FIG. 3 is an enlarged view of a main portion of the semiconductor device.

FIG. 4 is an enlarged view of a part, which is surrounded by an alternate long and short dashed line IV, of FIG. 3.

FIG. 5 is an enlarged view of a part, which is surrounded by an alternate long and short dashed line V, of FIG. 3.

FIG. 6 is a cross-sectional view along line VI-VI of FIG. 4.

FIG. 7 is a cross-sectional view along line VII-VII of FIG. 4.

FIG. 8 is a cross-sectional view along line VIII-VIII of FIG. 4.

FIG. 9 is a cross-sectional view along line IX-IX of FIG. 4.

FIG. 10 is an enlarged perspective view of the main portion of the semiconductor device.

FIG. 11A to FIG. 11K are views showing a part of a manufacturing process of the semiconductor device.

FIG. 12 is a view shown to describe a modification of an inspection wiring of FIG. 10.

FIG. 13 is a view shown to describe a modification of the inspection wiring of FIG. 10.

FIG. 14 is a view shown to describe a modification of the inspection wiring of FIG. 10.

FIG. 15 is a view shown to describe a modification of the inspection wiring of FIG. 10.

FIG. 16 is a view shown to describe a modification of the inspection wiring of FIG. 10.

FIG. 17 is a view shown to describe a modification of the inspection wiring of FIG. 10.

FIG. 18 is a view shown to describe a modification of the inspection wiring of FIG. 10.

FIG. 19 is a view shown to describe a modification of the inspection wiring of FIG. 10.

### DETAILED DESCRIPTION OF PREFERRED EMBODIMENTS

### [Entire Configuration of Semiconductor Device 1]

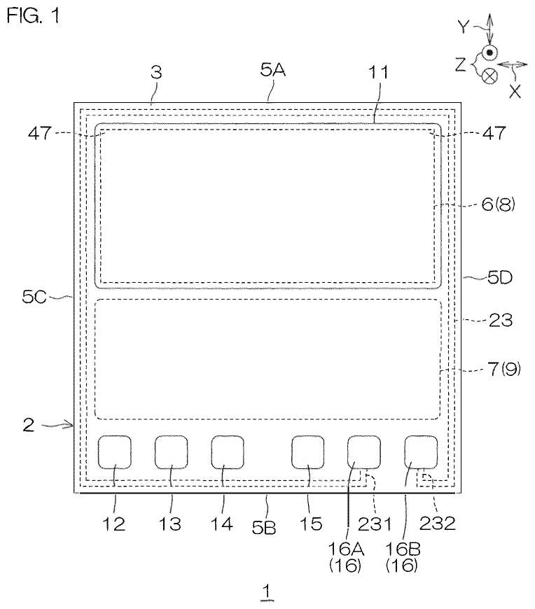

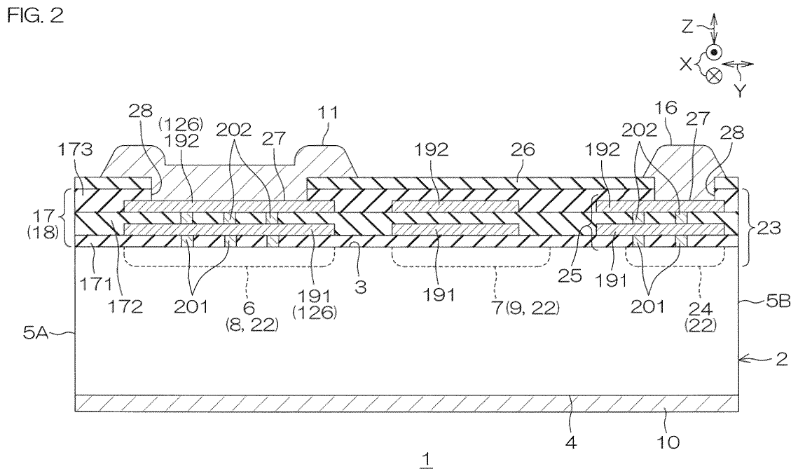

Next, a preferred embodiment of the present disclosure will be described in detail with reference to the accompanying drawings. The accompanying drawings are schematic views, and are not strictly shown, and do not necessarily coincide with each other in scale reduction and the like. FIG. 1 is a schematic plan view of a semiconductor device 1 according to a preferred embodiment of the present disclosure. FIG. 2 is a schematic cross-sectional view of the semiconductor device 1.

The semiconductor device 1 is an electronic component that is packaged with a sealing resin (not shown). The semiconductor device 1 includes a semiconductor chip 2 supported by a lead frame (not shown) of the sealing resin. In this preferred embodiment, the semiconductor chip 2 is constituted of a chip including Si (silicon), and is formed in a rectangular parallelepiped shape. The semiconductor chip 2 may be constituted of a chip including a Si monocrystal or a SiC monocrystal. The semiconductor chip 2 has a first principal surface 3 on one side, a second principal surface 4 on the other side (side opposite to the first principal surface 3), and first to fourth peripheral end surfaces 5A to 5D connecting the first and second principal surfaces 3 and 4. The first and second principal surfaces 3 and 4 are each formed in a quadrangular shape in a plan view seen from their normal directions Z (hereinafter, referred to simply as a “plan view”).

The first principal surface 3 is an element forming surface on which a functional element is formed. The second principal surface 4 is a mounting surface, and may be constituted of a ground surface having grinding marks. The first to fourth peripheral end surfaces 5A to 5D include a first peripheral end surface 5A, a second peripheral end surface 5B, a third peripheral end surface 5C, and a fourth peripheral end surface 5D. The first peripheral end surface 5A and the second peripheral end surface 5B extend in a first direction X along the first principal surface 3, and face each other in a second direction Y intersecting (in detail, perpendicularly intersecting) the first direction X. The third peripheral end surface 5C and the fourth peripheral end surface 5D extend in the second direction Y, and face each other in the first direction X.

The semiconductor chip 2 includes a first element region 6 provided in the first principal surface 3. The first element region 6 is an output region in which an output signal, which is output to the outside, is generated. In this preferred embodiment, the first element region 6 is divisionally formed in a region located on the first peripheral end surface 5A side in the first principal surface 3. The first element region 6 may be demarcated in a quadrangular shape in a plan view, or may be demarcated in a polygonal shape other than the quadrangular shape. The arrangement and the planar shape of the first element region 6 are arbitrary, and are not limited to a specific form.

For example, an insulated gate type main transistor 8 is formed in the first element region 6. The main transistor 8 may be referred to as a “gate divided transistor,” a “power transistor,” or a “power MISFET (Metal Insulator Semiconductor Field Effect Transistor).”

The semiconductor chip 2 includes a second element region 7 provided in a region differing from the first element region 6 in the first principal surface 3. The second element region 7 is an input region into which an electric signal from the outside is input. In this preferred embodiment, the second element region 7 is demarcated in a region located on the second peripheral end surface 5B side with respect to the first element region 6. The second element region 7 may be demarcated in a quadrangular shape in a plan view, or may be demarcated in a polygonal shape other than the quadrangular shape. The arrangement and the planar shape of the second element region 7 are arbitrary, and are not limited to a specific form.

Preferably, the second element region 7 has a plane area equal to or less than the plane area of the first element region 6. Preferably, the second element region 7 is formed at an area ratio of not less than 0.1 and not more than 1 with respect to the first element region 6. The area ratio is a ratio of the plane area of the second element region 7 to the plane area of the first element region 6. Preferably, the area ratio is less than 1. Of course, the second element region 7 having a plane area exceeding the plane area of the first element region 6 may be employed.

For example, a control IC 9 as an example of a control circuit is formed in the second element region 7. The control IC 9 composes an IPD (Intelligent Power Device) together with the main transistor 8. The IPD may be referred to as an “IPM (Intelligent Power Module).” The control IC 9 includes a plurality of kinds of functional circuits that realize various functions in response to an electric signal input from the outside. The functional circuits may include, although not shown, a gate control circuit, an active clamp circuit, and a plurality of kinds of malfunction detection circuits that detect abnormalities (for example, overvoltage, overheat, etc.) in the main transistor 8, in the functional circuit, or in like components.

The semiconductor chip 2 includes a plurality of terminal electrodes 10 to 16. The number, the arrangement, and the planar shape of the terminal electrodes 10 to 16 are adjusted so as to have arbitrary forms in accordance with the specifications of the main transistor 8 and in accordance with the specifications of the control IC 9, and are not limited to the forms shown in FIGS. 1 and 2. In this preferred embodiment, the terminal electrodes 10 to 16 include a drain terminal 10 (power terminal VBB), a source terminal 11 (output terminal OUT), an input terminal 12, a ground terminal 13, an enable terminal 14, a sense terminal 15, and an examination terminal 16.

The drain terminal 10 is electrically connected to the drain of the main transistor 8 and to the control IC 9. The drain terminal 10 transmits a power supply voltage VB to the drain of the main transistor 8 and to various circuits of the control IC 9. The source terminal 11 is electrically connected to the source of the main transistor 8 and to the control IC 9. The source terminal 11 transmits an output current IOUT generated by the main transistor 8 to the outside.

The input terminal 12 transmits an input voltage that drives the control IC 9. The ground terminal 13 transmits a ground voltage GND. The enable terminal 14 transmits an electric signal serving to enable or disable functions of part or all of the control IC 9. The sense terminal 15 transmits an electric signal serving to detect an abnormality of the main transistor 8 or of the control IC 9. The examination terminal 16 transmits an electric signal to an inspection wiring 23 (described later) in order to determine whether a chipping defect has occurred in the semiconductor chip 2. In this preferred embodiment, the examination terminal 16 includes a first examination terminal 16A and a second examination terminal 16B. The first examination terminal 16A and the second examination terminal 16B are arranged side by side with each other.

The drain terminal 10 directly covers the second principal surface 4 of the semiconductor chip 2, and is electrically connected to the second principal surface 4. The drain terminal 10 may include at least one among a Ti layer, an Ni layer, an Au layer, an Ag layer, and an Al layer. The drain terminal 10 may have a laminated structure in which at least two among the Ti layer, the Ni layer, the Au layer, the Ag layer, and the Al layer are laminated in an arbitrary manner.

The source terminal 11, the input terminal 12, the ground terminal 13, the enable terminal 14, the sense terminal 15, and the examination terminal 16 are disposed on an interlayer insulating layer 17 (an example of an insulating layer) on the first principal surface 3. The source terminal 11 is disposed over the first element region 6 in the first principal surface 3. The input terminal 12, the ground terminal 13, the enable terminal 14, the sense terminal 15, and the examination terminal 16 are each disposed over a region located outside the first element region 6 in the first principal surface 3. In this preferred embodiment, the input terminal 12, the ground terminal 13, the enable terminal 14, the sense terminal 15, and the examination terminal 16 are linearly arrayed at a distance from each other along one peripheral end surface (for example, the second peripheral end surface 5B).

The terminal electrodes 11 to 16 may include at least one type among a pure Al layer, a pure Cu layer, an AlCu alloy layer, an AlSiCu alloy layer, and an AlSi alloy layer. A plating layer may be formed on an outer surface of each of the terminal electrodes 11 to 16. The plating layer may include at least one type among an Ni layer, a Pd layer, and an Au layer.

Referring to FIG. 2, the semiconductor chip 2 includes a multilayer wiring structure 18 formed on the first principal surface 3. The multilayer wiring structure 18 includes the interlayer insulating layer 17, a plurality of wiring layers 19 that are embedded in the interlayer insulating layer 17 and that are laminated at a distance from each other inside the interlayer insulating layer 17, and a connection via 20 that connects the wiring layers 19. For example, the interlayer insulating layer 17 includes a silicon oxide film. For example, the wiring layer 19 may include at least one type among a pure Al layer, a pure Cu layer, an AlCu alloy layer, an AlSiCu alloy layer, and an AlSi alloy layer. For example, the connection via 20 may include a tungsten plug electrode.

In this preferred embodiment, the interlayer insulating layer 17 includes a first interlayer insulating layer 171, a second interlayer insulating layer 172, and a third interlayer insulating layer 173 that are laminated in that order from the first principal surface 3. The wiring layers 19 include a first wiring layer 191 and a second wiring layer 192. The first wiring layer 191 is formed on the first interlayer insulating layer 171, and is covered by the second interlayer insulating layer 172. The second wiring layer 192 is formed on the second interlayer insulating layer 172, and is covered by the third interlayer insulating layer 173. The first wiring layer 191 and the second wiring layer 192 may each have a plurality of wiring patterns that are physically and electrically separated from each other.

The connection via 20 includes a first connection via 201 and a second connection via 202. The first connection via 201 electrically connects the first wiring layer 191 and a chip internal structure 22 formed at a surficial portion of the first principal surface 3. For example, the chip internal structure 22 may include an internal wiring portion 24 (described later) of the inspection wiring 23 (described later) in addition to both the main transistor 8 mentioned above and the control IC 9 mentioned above. The second connection via 202 electrically connects the second wiring layer 192 and the first wiring layer 191.

The inspection wiring 23 is formed by use of a part of the multilayer wiring structure 18 in the semiconductor chip 2. Referring to FIG. 1, the inspection wiring 23 is formed on the first principal surface 3 side along the first to fourth peripheral end surfaces 5A to 5D, and surrounds the first element region 6 and the second element region 7. The inspection wiring 23 is formed over the entirety of an outer peripheral edge portion of the semiconductor chip 2, and has one end 231 and the other end 232 that are joined together near one peripheral end surface (in FIG. 1, the second peripheral end surface 5B). The end 231 and the other end 232 of the inspection wiring 23 are connected to the first examination terminal 16A and the second examination terminal 16B, respectively. In this preferred embodiment, the inspection wiring 23 is formed in a substantially quadrangular annular shape having four sides parallel to the first to fourth peripheral end surfaces 5A to 5D in a plan view. The planar shape of the inspection wiring 23 is arbitrary, and may be formed in a substantially polygonal annular shape.

Referring to FIG. 2, the inspection wiring 23 includes the internal wiring portion 24 and an extending wiring portion 25. The internal wiring portion 24 is formed at the surficial portion of the first principal surface 3 of the semiconductor chip 2. Here, the formation of a structural component at the surficial portion of the first principal surface 3 may denote the formation of the structural component at an inward part, which is near the first principal surface 3, of the semiconductor chip 2 by applying a processing operation to the first principal surface 3 of the semiconductor chip 2. The extending wiring portion 25 is a structure connected to the internal wiring portion 24 by use of the multilayer wiring structure 18. The extending wiring portion 25 may be referred to as “a construction wiring portion” or “a straddle wiring portion”. In this preferred embodiment, the extending wiring portion 25 may include the first wiring layer 191, the second wiring layer 192, the first connection via 201, and the second connection via 202.

A passivation film 26 is formed on the interlayer insulating layer 17. For example, the passivation film 26 includes a silicon nitride film. A pad opening 28 that exposes a part of an uppermost layer wiring of the multilayer wiring structure 18 (in FIG. 2, the second wiring layer 192) as a pad 27 is formed in the passivation film 26. The terminal electrodes 11 to 16 are formed on the passivation film 26, and are connected to the pad 27 through the pad opening 28. As an example, a connection mode between the source terminal 11 and the pad 27 and a connection mode between the examination terminal 16 and the pad 27 are shown in FIG. 2.

### [Detailed Description of Main Transistor 8]

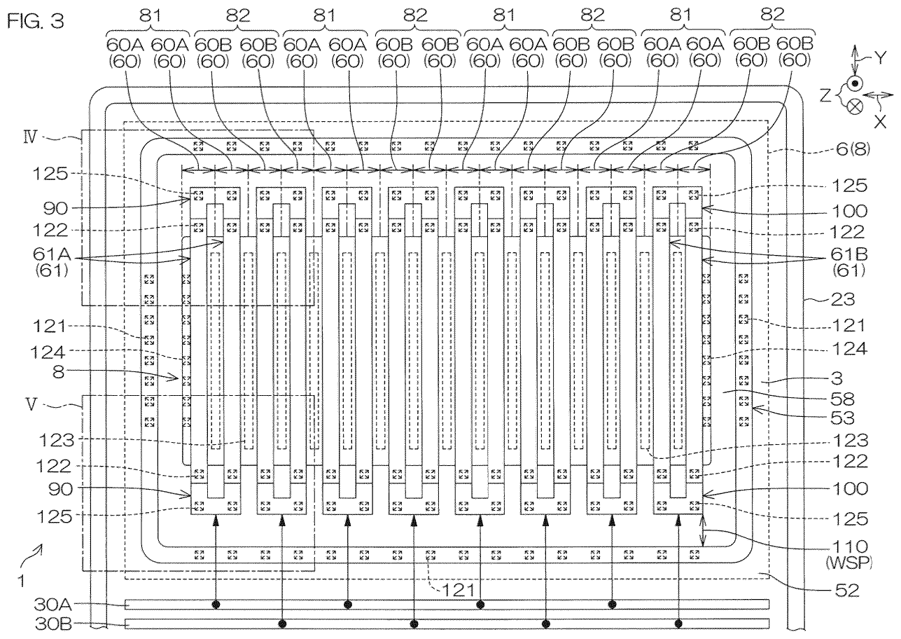

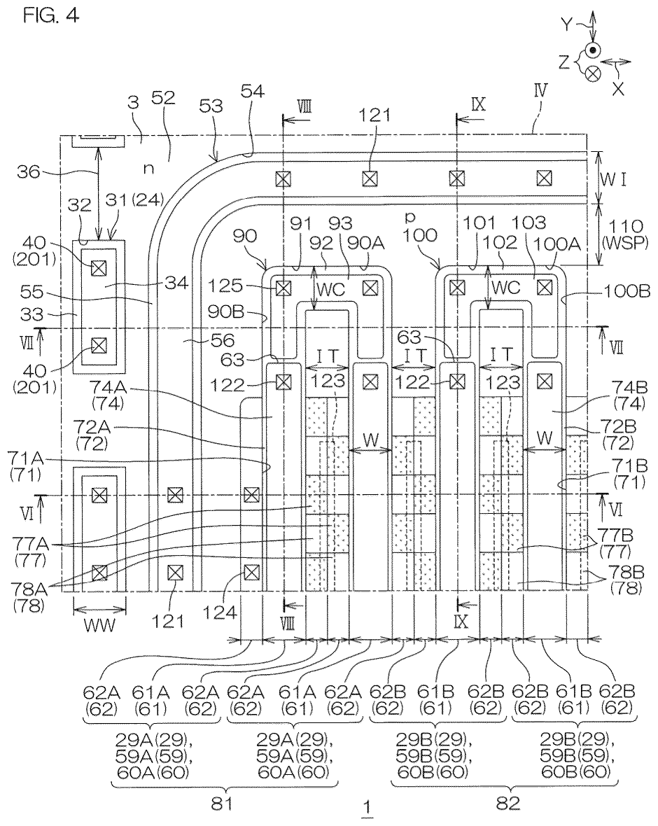

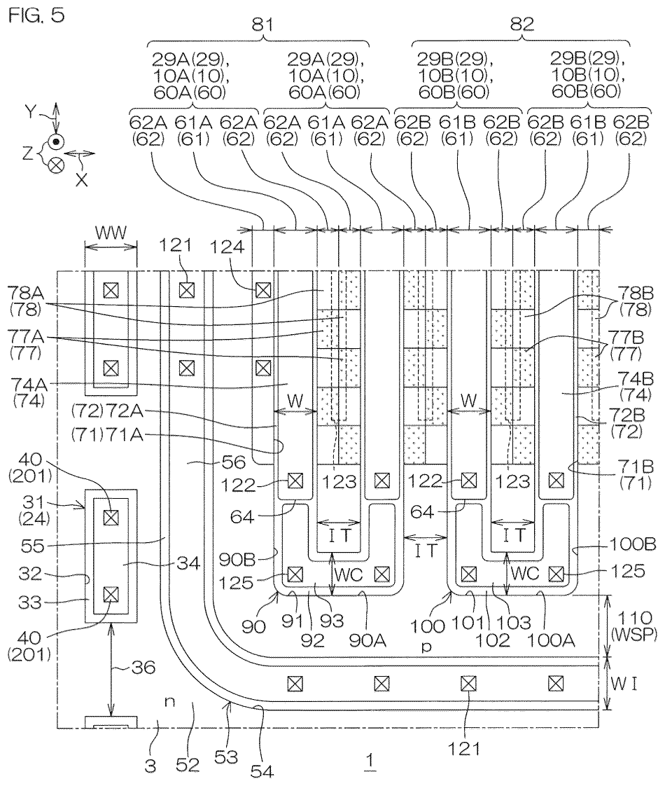

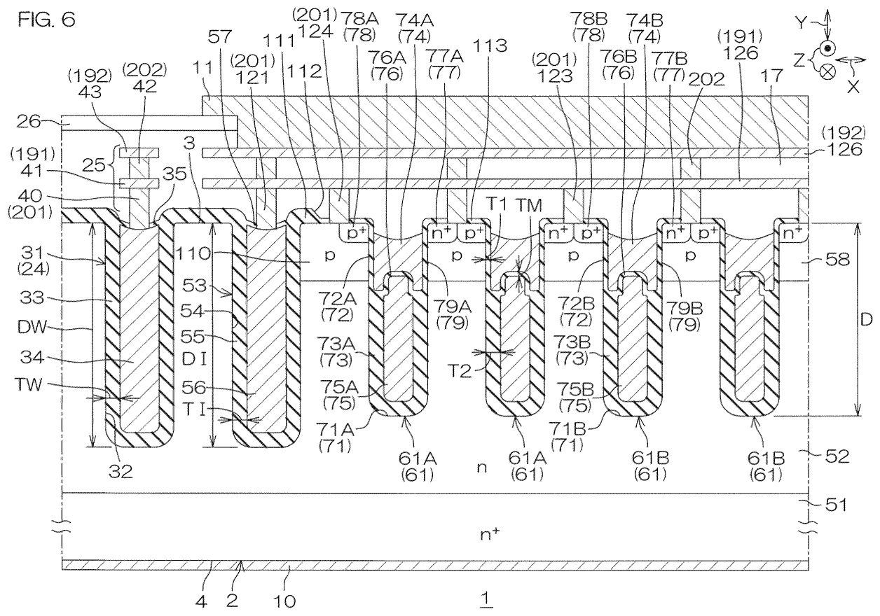

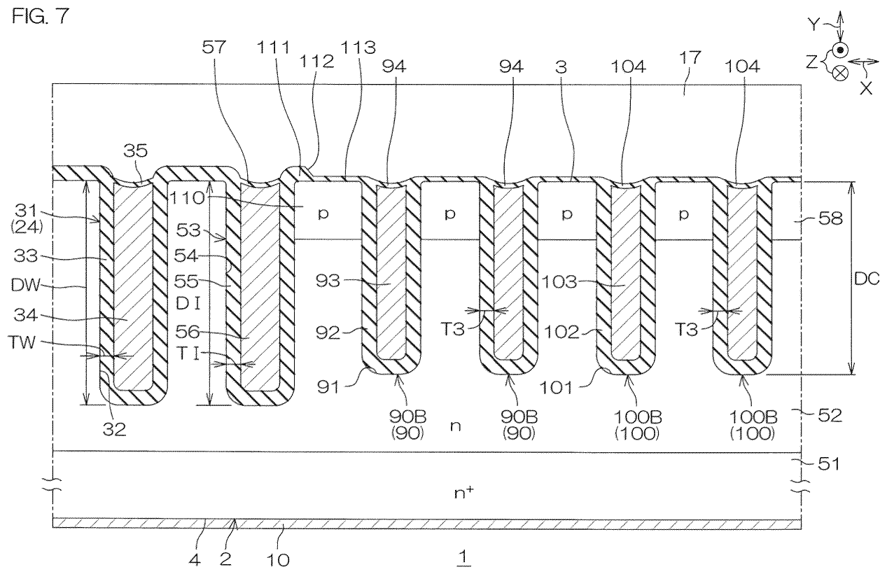

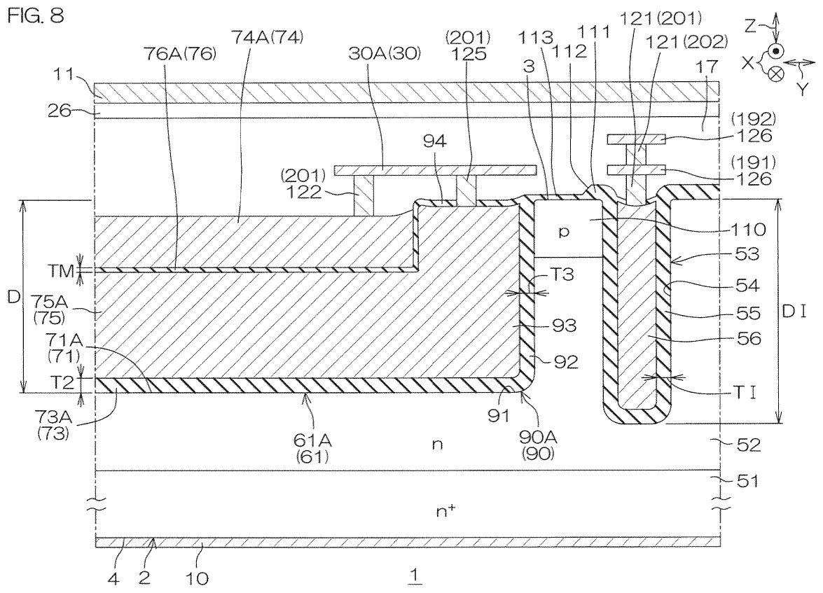

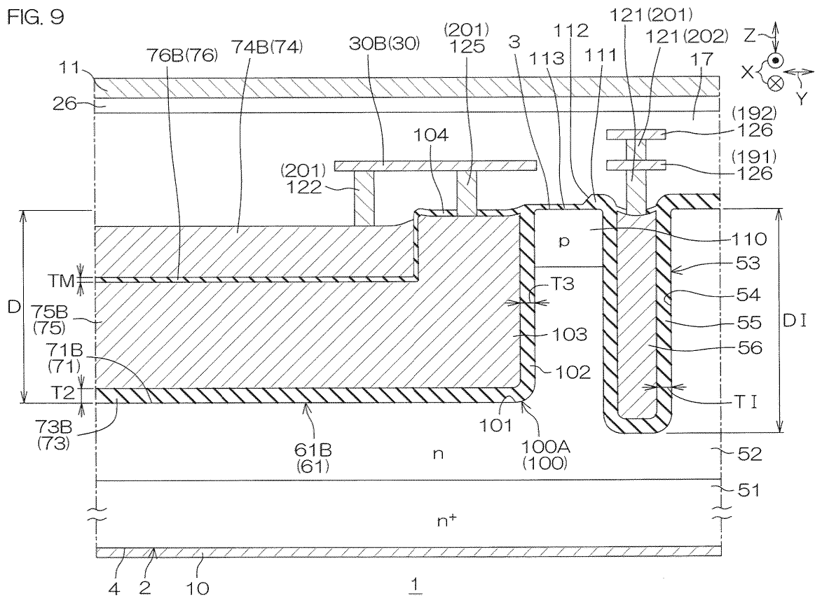

FIG. 3 is an enlarged view of a main portion of the semiconductor device 1. FIG. 4 is an enlarged view of a part, which is surrounded by an alternate long and short dashed line IV, of FIG. 3. FIG. 5 is an enlarged view of a part, which is surrounded by an alternate long and short dashed line V, of FIG. 3. FIG. 6 is a cross-sectional view along line VI-VI of FIG. 4. FIG. 7 is a cross-sectional view along line VII-VII of FIG. 4. FIG. 8 is a cross-sectional view along line VIII-VIII of FIG. 4. FIG. 9 is a cross-sectional view along line IX-IX of FIG. 4.

Referring to FIG. 3 to FIG. 9, the semiconductor device 1 includes an n-type (first conductivity type) first semiconductor region 51 formed at a surficial portion of the second principal surface 4 of the semiconductor chip 2. The first semiconductor region 51 forms the drain of the main transistor 8. The first semiconductor region 51 may be referred to as a drain region. The first semiconductor region 51 is formed in the whole area of the surficial portion of the second principal surface 4, and is exposed from the second principal surface 4 and from the first to fourth peripheral end surfaces 5A to 5D.

The n-type impurity concentration of the first semiconductor region 51 may be not less than 1×10¹⁸ cm⁻³ and not more than 1×10²¹ cm⁻³. The thickness of the first semiconductor region 51 may be not less than 10 μm and not more than 450 μm. Preferably, the thickness of the first semiconductor region 51 is not less than 50 μm and not more than 150 μm. In this preferred embodiment, the first semiconductor region 51 is constituted of an n-type semiconductor substrate (Si substrate).

The semiconductor device 1 includes an n-type second semiconductor region 52 formed at the surficial portion of the first principal surface 3 of the semiconductor chip 2. The second semiconductor region 52 forms the drain of the main transistor 8 together with the first semiconductor region 51. The second semiconductor region 52 may be referred to as a “drift region.” The second semiconductor region 52 is formed in the whole area of the surficial portion of the first principal surface 3 so as to be electrically connected to the first semiconductor region 51, and is exposed from the first principal surface 3 and from the first to fourth peripheral end surfaces 5A to 5D.

The second semiconductor region 52 has an n-type impurity concentration less than the n-type impurity concentration of the first semiconductor region 51. The n-type impurity concentration of the second semiconductor region 52 may be not less than 1×10¹⁵ cm⁻³ and not more than 1×10¹⁸ cm⁻³. The second semiconductor region 52 has a thickness less than the thickness of the first semiconductor region 51. The thickness of the second semiconductor region 52 may be not less than 1 μm and not more than 25 μm. Preferably, the thickness of the second semiconductor region 52 is not less than 5 μm and not more than 15 μm. In this preferred embodiment, the second semiconductor region 52 is constituted of an n-type epitaxial layer (Si epitaxial layer).

The semiconductor device 1 includes a trench separation structure 53 as an example of a region separation structure that divisionally forms the first element region 6 in the first principal surface 3. The trench separation structure 53 may be referred to as a “DTI (deep trench isolation) structure.” The trench separation structure 53 is formed in an annular shape surrounding a region of a part of the first principal surface 3 in a plan view, and divisionally forms the first element region 6 having a predetermined shape.

In this preferred embodiment, the trench separation structure 53 is formed in a quadrangular annular shape having four sides parallel to the first to fourth peripheral end surfaces 5A to 5D in a plan view, and divisionally forms the first element region 6 having a quadrangular shape. The planar shape of the trench separation structure 53 is arbitrary, and may be formed in a polygonal annular shape. The first element region 6 may be demarcated in a polygonal shape in accordance with the planar shape of the trench separation structure 53.

The trench separation structure 53 has a separation width WI and a separation depth DI. The separation width WI is a width in a direction perpendicular to a direction in which the trench separation structure 53 extends in a plan view. The separation width WI may be not less than 0.5 μm and not more than 2.5 μm. Preferably, the separation width WI is not less than 1.2 μm and not more than 2 μm. The separation depth DI may be not less than 1 μm and not more than 10 μm. Preferably, the separation depth DI is not less than 2 μm and not more than 6 μm.

An aspect ratio DI/WI of the trench separation structure 53 may be more than 1 and not more than 5. The aspect ratio DI/WI is a ratio of the separation depth DI to the separation width WI. Preferably, the aspect ratio DI/WI is equal to or more than 2. Preferably, a bottom wall of the trench separation structure 53 is at a distance of not less than 1 μm and not more than 5 μm from a bottom portion of the second semiconductor region 52.

The trench separation structure 53 has a corner portion that connects a part extending in the first direction X and a part extending in the second direction Y in a circular arc shape (curved shape). In this preferred embodiment, four corners of the trench separation structure 53 are each formed in a circular arc shape. In other words, the first element region 6 is demarcated in a quadrangular shape having four corners each of which extends in a circular arc shape. Preferably, the corner portion of the trench separation structure 53 has a predetermined separation width WI along a circular arc direction.

The trench separation structure 53 has a single electrode structure including a separation trench 54, a separation insulating film 55 (separation insulating layer), a separation electrode 56 (separation conductive layer), and a separation cap insulating film 57. The separation trench 54 is dug down from the first principal surface 3 toward the second principal surface 4. The separation trench 54 is formed at a distance from the bottom portion of the second semiconductor region 52 toward the first principal surface 3 side.

The separation trench 54 includes a sidewall and a bottom wall. The angle of the sidewall of the separation trench 54 with the first principal surface 3 in the semiconductor chip 2 may be not less than 90° and not more than 92°. The separation trench 54 may be formed in a tapered shape in which an opening width becomes smaller from an opening toward the bottom wall. Preferably, the corner portion of the bottom wall of the separation trench 54 is formed in a curved shape. The entirety of the bottom wall of the separation trench 54 may be formed so as to be curved toward the second principal surface 4.

The separation insulating film 55 is formed on a wall surface of the separation trench 54. In detail, the separation insulating film 55 is formed as a film in the whole area of the wall surface of the separation trench 54, and divisionally forms a recessed space in the separation trench 54. Preferably, the separation insulating film 55 includes a silicon oxide film. Particularly preferably, the separation insulating film 55 includes a silicon oxide film constituted of an oxide of the semiconductor chip 2.

The separation insulating film 55 has a separation thickness TI. The separation thickness TI is a thickness along the normal direction of the wall surface of the separation trench 54. The separation thickness TI may be not less than 0.1 μm and not more than 1 μm. Preferably, the separation thickness TI is not less than 0.15 μm and not more than 0.65 μm. The thickness of a part, which covers the bottom wall of the separation trench 54, of the separation insulating film 55 may be less than the thickness of a part, which covers the sidewall of the separation trench 54, of the separation insulating film 55.

The separation electrode 56 is embedded in the separation trench 54 as an integrated member with the separation insulating film 55 between the separation electrode 56 and the separation trench 54. In this preferred embodiment, the separation electrode 56 includes conductive polysilicon. A source potential is applied to the separation electrode 56. The separation electrode 56 has an electrode surface (separation electrode surface) exposed from the separation trench 54. The electrode surface of the separation electrode 56 may be hollowed so as to be curved toward the bottom wall of the separation trench 54. Preferably, the electrode surface of the separation electrode 56 is at a distance of greater than 0 Å and less than 2000 Å from the first principal surface 3 to the bottom wall of the separation trench 54 with regard to the depth direction of the separation trench 54. Particularly preferably, the electrode surface of the separation electrode 56 is at a distance of less than 1000 Å from the first principal surface 3 to the bottom wall of the separation trench 54.

The separation cap insulating film 57 covers the electrode surface of the separation electrode 56 in the separation trench 54 as a film. The separation cap insulating film 57 suppresses a short circuit of the separation electrode 56 with another electrode. The separation cap insulating film 57 is continuous with the separation insulating film 55. Preferably, the separation cap insulating film 57 includes a silicon oxide film. Particularly preferably, the separation cap insulating film 57 includes a silicon oxide film constituted of an oxide of the separation electrode 56. In other words, preferably, the separation cap insulating film 57 includes an oxide of polysilicon, and the separation insulating film 55 includes an oxide of a silicon monocrystal.

The semiconductor device 1 includes a p-type (second conductivity type) body region 58 formed at the surficial portion of the first principal surface 3 in the first element region 6. The p-type impurity concentration of the body region 58 may be not less than 1×10¹⁶ cm⁻³ and not more than 1×10¹⁸ cm⁻³. The body region 58 is formed in the whole area of the surficial portion of the first principal surface 3 in the first element region 6, and is contiguous to the sidewall of the trench separation structure 53. The body region 58 is formed in a region on the first principal surface 3 side with respect to the bottom wall of the trench separation structure 53. Preferably, the body region 58 is formed in a region on the first principal surface 3 side with respect to an intermediate portion of the trench separation structure 53.

The semiconductor device 1 includes the 2-system main transistor 8 (n=2) formed at the first principal surface 3 in the first element region 6. The main transistor 8 is formed at the first principal surface 3 at a distance from the trench separation structure 53 in a plan view. The main transistor 8 includes a plurality of unit transistors 59 that are intensively formed at the first principal surface 3 of the first element region 6.

The number of the unit transistor 59 is arbitrary. FIG. 3 shows an example in which sixteen unit transistors 59 are formed. Preferably, the number of the unit transistors 59 is an even number. The unit transistors 59 are formed so as to be arrayed in a line in the first direction X, and are each formed in a belt shape extending in the second direction Y in a plan view. The unit transistors 59 are formed in a stripe shape extending in the second direction Y in a plan view.

In detail, each of the unit transistors 59 consists of a unit cell 60. Each of the unit cells 60 includes a single trench structure 61 and a channel cell 62 controlled by this trench structure 61. The trench structure 61 may be referred to as a “gate structure” or a “trench gate structure.” Each of the trench structures 61 forms a third gate TG of each of the unit transistors 59. The channel cell 62 is a region in which the opening and closing of a current path are controlled by the trench structure 61. In this preferred embodiment, the unit cell 60 includes a pair of channel cells 62 formed at both sides of the single trench structure 61.

The trench structures 61 are arrayed at a distance from each other in the first direction X, and are each formed in a belt shape extending in the second direction Y in a plan view. In other words, the trench structures 61 are formed in a stripe shape extending in the second direction Y in a plan view. Each of the trench structures 61 has a first end portion 63 on one side and a second end portion 64 on the other side with regard to a longitudinal direction (second direction Y).

Each of the trench structures 61 has a trench width W and a trench depth D. The trench width W is a width in a direction (first direction X) perpendicular to a direction in which the trench structure 61 extends. Preferably, the trench width W is less than the separation width WI of the trench separation structure 53 (W<WI). The trench width W may be not less than 0.5 μm and not more than 2 μm. Preferably, the trench width W is not less than 0.5 μm and not more than 1.5 μm. Of course, the trench width W may be substantially equal to the separation width WI (W≈WI).

Preferably, the trench depth D is less than the separation depth DI of the trench separation structure 53 (D<DI). The trench depth D may be not less than 1 μm and not more than 10 μm. Preferably, the trench depth D is not less than 2 μm and not more than 6 μm. Of course, the trench depth D may be substantially equal to the separation depth DI (D≈DI).

An aspect ratio D/W of the trench structure 61 may be more than 1 and not more than 5. The aspect ratio D/W is the ratio of the trench depth D to the trench width W. Particularly preferably, the aspect ratio D/W is 2 or more. Preferably, a bottom wall of the trench structure 61 is at a distance of not less than 1 μm and not more than 5 μm from the bottom portion of the second semiconductor region 52.

The trench structures 61 are arrayed with a trench interval IT between the trench structures 61 in the first direction X. Preferably, the trench interval IT is set so as to have a value at which depletion layers spreading from the trench structures 61 are united with each other below the bottom wall of the trench structures 61. The trench interval IT may be 0.25 times or more as wide as the trench width W and be 1.5 times or less as wide as the trench width W. Preferably, the trench interval IT is equal to or less than the trench width W (IT≤W). The trench interval IT may be not less than 0.5 μm and not more than 2 μm.

A configuration of the single trench structure 61 will be hereinafter described. The trench structure 61 has a multi-electrode structure including a trench 71, an upper insulating film 72, a lower insulating film 73, an upper electrode 74, a lower electrode 75, and an intermediate insulating film 76. The trench 71 may be referred to as a “gate trench.” The trench structure 61 includes an embedded electrode (gate electrode) embedded in the trench 71 with a buried insulator between the buried electrode and the trench 71. The embedded insulator is composed of the upper insulating film 72, the lower insulating film 73, and the intermediate insulating film 76. The embedded electrode is composed of the upper electrode 74 and the lower electrode 75.

The trench 71 is dug down from the first principal surface 3 toward the second principal surface 4. The trench 71 penetrates through the body region 58, and is formed at a distance from the bottom portion of the second semiconductor region 52 toward the first principal surface 3 side. The trench 71 includes a sidewall and a bottom wall. The angle of the sidewall of the trench 71 with the first principal surface 3 in the semiconductor chip 2 may be not less than 90° and not more than 92°. The trench 71 may be formed in a tapered shape whose opening width becomes smaller from an opening toward the bottom wall. Preferably, a corner portion of the bottom wall of the trench 71 is formed in a curved shape. The entirety of the bottom wall of the trench 71 may be formed so as to be curved toward the second principal surface 4.

The upper insulating film 72 covers an upper wall surface of the trench 71. In detail, the upper insulating film 72 covers an upper wall surface, which is located in a region on the opening side with respect to a bottom portion of the body region 58, of the trench 71. The upper insulating film 72 crosses a boundary between the second semiconductor region 52 and the body region 58. The upper insulating film 72 has its part that covers the body region 58 and its part that covers the second semiconductor region 52. The covering area of the upper insulating film 72 with respect to the body region 58 is larger than the covering area of the upper insulating film 72 with respect to the second semiconductor region 52. Preferably, the upper insulating film 72 includes a silicon oxide film. Particularly preferably, the upper insulating film 72 includes a silicon oxide film constituted of an oxide of the semiconductor chip 2. The upper insulating film 72 is formed as a gate insulating film.

The upper insulating film 72 has a first thickness T1. The first thickness T1 is a thickness along the normal direction of the wall surface of the trench 71. The first thickness T1 is less than the separation thickness TI of the separation insulating film 55 (T1<TI). For example, the first thickness T1 may be not less than 0.005 μm and not more than 0.1 μm, and, preferably, not less than 0.01 μm and not more than 0.1 μm, and, more preferably, not less than 0.02 μm and not more than 0.05 μm.

The lower insulating film 73 covers a lower wall surface of the trench 71. In detail, the lower insulating film 73 covers a lower wall surface located in a region on the bottom wall side of the trench 71 with respect to the bottom portion of the body region 58. The lower insulating film 73 divisionally forms a recessed space in the region on the bottom wall side of the trench 71. The lower insulating film 73 is contiguous to the second semiconductor region 52. Preferably, the lower insulating film 73 includes a silicon oxide film. Particularly preferably, the lower insulating film 73 includes a silicon oxide film constituted of an oxide of the semiconductor chip 2.

The lower insulating film 73 has a second thickness T2. The second thickness T2 is a thickness along the normal direction of the wall surface of the trench 71. The second thickness T2 exceeds the first thickness T1 of the upper insulating film 72 (T1<T2). The second thickness T2 may be substantially equal to the separation thickness TI of the separation insulating film 55 (T2≈TI). The second thickness T2 may be not less than 0.1 μm and not more than 1 μm. Preferably, the second thickness T2 is not less than 0.15 μm and not more than 0.65 μm. The thickness of a part, which covers the bottom wall of the trench 71, of the lower insulating film 73 may be less than the thickness of a part, which covers the sidewall of the trench 71, of the lower insulating film 73.

The upper electrode 74 is embedded at the upper side (opening side) in the trench 71 with the upper insulating film 72 between the upper electrode 74 and the trench 71. The upper electrode 74 is embedded in a belt shape extending in the second direction Y in a plan view. The upper electrode 74 faces both the body region 58 and the second semiconductor region 52 across the upper insulating film 72. The facing area of the upper electrode 74 with respect to the body region 58 is larger than the facing area of the upper electrode 74 with respect to the second semiconductor region 52. The upper electrode 74 includes conductive polysilicon. The upper electrode 74 is formed as a gate electrode. A gate signal G is input into the upper electrode 74.

The upper electrode 74 has an electrode surface (embedded electrode surface) exposed from the trench 71. The electrode surface of the upper electrode 74 may be hollowed so as to be curved toward the bottom wall of the trench 71. Preferably, the electrode surface of the upper electrode 74 is located closer to the bottom wall side of the trench 71 than the depth position of the electrode surface of the separation electrode 56 with regard to the depth direction of the trench 71. Preferably, the electrode surface of the upper electrode 74 is at a distance of 2000 Å or more from the first principal surface 3 to the bottom wall of the trench 71 with regard to the depth direction of the trench 71. Particularly preferably, the electrode surface of the upper electrode 74 is at a distance of not less than 2500 Å and not more than 4500 Å from the first principal surface 3 to the bottom wall of the trench 71.

The lower electrode 75 is embedded at the lower side (bottom wall side) in the trench 71 with the lower insulating film 73 between the lower electrode 75 and the trench 71. The lower electrode 75 is embedded in a belt shape extending in the second direction Y in a plan view. The lower electrode 75 has a thickness (length) exceeding the thickness (length) of the upper electrode 74 with regard to the depth direction of the trench 71. The lower electrode 75 faces the second semiconductor region 52 across the lower insulating film 73. The lower electrode 75 has an upper end portion that protrudes from the lower insulating film 73 toward the first principal surface 3 side. The upper end portion of the lower electrode 75 bites the bottom portion of the upper electrode 74, and faces the upper insulating film 72 across the bottom portion of the upper electrode 74 in a lateral direction along the first principal surface 3.

The lower electrode 75 includes conductive polysilicon. In this preferred embodiment, the lower electrode 75 is formed as a gate electrode. The lower electrode 75 is fixed at the same potential as the upper electrode 74. In other words, the same gate signal G is applied to the lower electrode 75 simultaneously with the upper electrode 74. This makes it possible to suppress a drop in voltage between the upper electrode 74 and the lower electrode 75, hence making it possible to suppress electric field concentration between the upper electrode 74 and the lower electrode 75. Additionally, it is possible to reduce the on-resistance of the semiconductor chip 2 (particularly, the second semiconductor region 52).

The intermediate insulating film 76 is interposed between the upper electrode 74 and the lower electrode 75, and electrically insulates the upper electrode 74 and the lower electrode 75 from each other. In detail, the intermediate insulating film 76 covers the lower electrode 75 exposed from the lower insulating film 73 in a region between the upper electrode 74 and the lower electrode 75. The intermediate insulating film 76 is continuous with the upper insulating film 72 and the lower insulating film 73. Preferably, the intermediate insulating film 76 includes a silicon oxide film. Particularly preferably, the intermediate insulating film 76 includes a silicon oxide film constituted of an oxide of the lower electrode 75.

The intermediate insulating film 76 has an intermediate thickness TM in the normal direction Z. The intermediate thickness TM is less than the second thickness T2 of the lower insulating film 73 (TM<T2). For example, the intermediate thickness TM may be not less than 0.005 μm and not more than 0.1 μm, and, preferably, not less than 0.01 μm and not more than 0.1 μm, and, more preferably, not less than 0.02 μm and not more than 0.05 μm.

The pair of channel cells 62 are each formed in a belt shape extending in the second direction Y on both sides of each of the trench structures 61. The pair of channel cells 62 have a length less than the length of the trench structure 61 with regard to the second direction Y. The whole area of the pair of channel cells 62 faces the upper electrode 74 across the upper insulating film 72. Each of the pair of channel cells 62 has a channel width corresponding to a value that is ½ times as wide as the trench interval IT.

The pair of channel cells 62 include at least one n-type source region 77 formed at a surficial portion of the body region 58. The number of the source regions 77 included in the pair of channel cells 62 is arbitrary. In this preferred embodiment, each of the pair of channel cells 62 includes the source regions 77. All source regions 77 included in each of the unit cells 60 form the source of each of the unit transistors 59.

The n-type impurity concentration of the source region 77 exceeds the n-type impurity concentration of the second semiconductor region 52. The n-type impurity concentration of the source region 77 may be not less than 1×10¹⁸ cm⁻³ and not more than 1×10²¹ cm⁻³. The source regions 77 are formed in a region on the first principal surface 3 side at a distance from the bottom portion of the body region 58, and face the upper electrode 74 across the upper insulating film 72. The source regions 77 are arrayed at a distance from each other in the second direction Y in each of the channel cells 62. In other words, the source regions 77 are arrayed at a distance from each other along a corresponding one of the trench structures 61 on both sides of the corresponding trench structure 61.

The pair of channel cells 62 include at least one p-type contact region 78 formed in a region, which differs from the source region 77, of the surficial portion of the body region 58. The number of the contact regions 78 included in the pair of channel cells 62 is arbitrary. In this preferred embodiment, each of the pair of channel cells 62 includes the contact regions 78. The p-type impurity concentration of the contact region 78 exceeds the p-type impurity concentration of the body region 58. The p-type impurity concentration of the contact region 78 may be not less than 1×10¹⁸ cm⁻³ and not more than 1×10²¹ cm⁻³.

The contact regions 78 are formed in a region on the first principal surface 3 side at a distance from the bottom portion of the body region 58, and face the upper electrode 74 across the upper insulating film 72. The contact regions 78 are formed alternately with the source regions 77 in the second direction Y in a manner in which the single source region 77 is interposed between the contact regions 78. In other words, the contact regions 78 are arrayed at a distance from each other along a corresponding one of the trench structures 61 on both sides of the corresponding trench structure 61.

The pair of channel cells 62 include a plurality of channel regions 79 formed between the source regions 77 and the second semiconductor region 52 in the body region 58. The on/off of the channel regions 79 in the pair of channel cells 62 is controlled by the single trench structure 61. The channel regions 79 included in the pair of channel cells 62 form a single channel of the unit transistor 59. Hence, the single unit cell 60 functions as the single unit transistor 59.

In this preferred embodiment, two unit cells 60 disposed on both sides in the first direction X in the first element region 6 do not include the source region 77 in the channel cell 62 on the trench separation structure 53 side. The thus formed structure makes it possible to suppress a leakage current between the trench structure 61 and the trench separation structure 53. In this preferred embodiment, the two unit cells 60 disposed on both sides include only the contact region 78 (hereinafter, referred to as the “outermost contact region 78”) in the channel cell 62 on the trench separation structure 53 side. The outermost contact region 78 is formed at a distance from the trench separation structure 53 toward the trench structure 61 side, and is connected to the sidewall of a corresponding one of the trench structures 61. The outermost contact region 78 may be formed in a belt shape extending along the sidewall of the corresponding trench structure 61.

The main transistor 8 includes two (n=2) system transistors 29 intensively formed in the first element region 6. The two system transistors 29 include a first system transistor 29A and a second system transistor 29B. The first system transistor 29A includes a plurality of (in this preferred embodiment, eight) first unit transistors 59A that are systematized selectively from the unit transistors 59 as a to-be-individually-controlled component.

The second system transistor 29B includes a plurality of (in this preferred embodiment, eight) second unit transistors 59B that are systematized selectively from the unit transistors 59 excluding the first unit transistor 59A as a to-be-individually-controlled component. The number of the second unit transistors 59B may differ from the number of the first unit transistors 59A. Preferably, the number of the second unit transistors 59B is equal to the number of the first unit transistors 59A.

The “unit cell 60,” the “trench structure 61,” the “channel cell 62,” the “trench 71,” the “upper insulating film 72,” the “lower insulating film 73,” the “upper electrode 74,” the “lower electrode 75,” the “intermediate insulating film 76,” the “source region 77,” the “contact region 78,” and the “channel region 79” of the first unit transistor 59A are hereinafter referred to as a “first unit cell 60A,” a “first trench structure 61A,” a “first channel cell 62A,” a “first trench 71A,” a “first upper insulating film 72A,” a “first lower insulating film 73A,” a “first upper electrode 74A,” a “first lower electrode 75A,” a “first intermediate insulating film 76A,” a “first source region 77A,” a “first contact region 78A,” and a “first channel region 79A,” respectively. A first gate signal G1 is input into the first upper electrode 74A and the first lower electrode 75A.

The “unit cell 60,” the “trench structure 61,” the “channel cell 62,” the “trench 71,” the “upper insulating film 72,” the “lower insulating film 73,” the “upper electrode 74,” the “lower electrode 75,” the “intermediate insulating film 76,” the “source region 77,” the “contact region 78,” and the “channel region 79” of the second unit transistor 59B are hereinafter referred to as a “second unit cell 60B,” a “second trench structure 61B,” a “second channel cell 62B,” a “second trench 71B,” a “second upper insulating film 72B,” a “second lower insulating film 73B,” a “second upper electrode 74B,” a “second lower electrode 75B,” a “second intermediate insulating film 76B,” a “second source region 77B,” a “second contact region 78B,” and a “second channel region 79B,” respectively. A second gate signal G2 that is electrically independent of the first gate signal G1 is input into to the second upper electrode 74B and the second lower electrode 75B.

The first system transistor 29A includes at least one first composite cell 81. The first composite cell 81 is arbitrary in number, and is adjusted in accordance with the size of the first element region 6 (total number of the unit transistors 59). In this preferred embodiment, the first system transistor 29A includes a plurality of (in this preferred embodiment, four) first composite cells 81. The first composite cells 81 are each composed of α number of (α≥2) first unit transistors 59A (the first unit cell 60A) arrayed so as to adjoin the first principal surface 3 in a plan view. The first composite cells 81 are arrayed at a distance from each other in the first direction X in a plan view.

The second system transistor 29B includes at least one second composite cell 82. The second composite cell 82 is arbitrary in number, and is adjusted in accordance with the size of the first element region 6 (total number of the unit transistors 59). The number of the second composite cells 82 may differ from the number of the first composite cells 81. Preferably, the number of the second composite cells 82 is equal to the number of the first composite cells 81. In this preferred embodiment, the second system transistor 29B includes a plurality of (in this preferred embodiment, four) second composite cells 82. The second composite cells 82 are each composed of β number of (β≥2) second unit transistors 59B (the second unit cell 60B) arrayed so as to adjoin the first principal surface 3 in a plan view.

The second composite cells 82 are disposed so as to adjoin the first composite cells 81, respectively, in a plan view. In detail, the second composite cells 82 are each disposed in a region between adjacent first composite cells 81 in a plan view. In more detail, the second composite cells 82 are arrayed alternately with the first composite cells 81 along the first direction X in a manner in which the single first composite cell 81 is interposed between the second composite cells 82 in a plan view.

The number of the first unit transistors 59A included in the single first composite cell 81 may be set as one (α=1), and the number of the second unit transistors 59B included in the single second composite cell 82 may be set as one (β=1). In other words, the second unit transistors 59B may be arrayed alternately with the first unit transistors 59A in a manner in which the single unit transistor 59 is interposed between the second unit transistors 59B in a plan view.

However, in this case, the number of the first and second unit transistors 59A and 59B facing each other increases. As a result, because of process errors and the like, a short circuit risk between the first and second unit transistors 59A and 59B adjacent to each other increases. The term “short circuit” mentioned here denotes a short circuit between the first trench structure 61A of the first unit transistor 59A and the second trench structure 61B of the second unit transistor 59B.

For example, if the single first unit transistor 59A short-circuits the single second unit transistor 59B adjacent to the first unit transistor 59A, all of the first unit transistors 59A are short-circuited by all of the second unit transistors 59B. In other words, the first and second system transistors 29A and 29B function as the single system transistor 29, and, as a result, the first system transistor 29A and the second system transistor 29B do not compose the 2-system main transistor 8.

Therefore, preferably, the number of the first unit transistors 59A included in the single first composite cell 81 is two or more (α≥2), and, preferably, the number of the second unit transistors 59B included in the single second composite cell 82 is two or more (β≥2). This structure makes it possible to reduce the number of the first and second unit transistors 59A and 59B facing each other. As a result, it is possible to reduce a short circuit risk between the first and second unit transistors 59A and 59B adjacent to each other.

In this case, preferably, the electrode surface of the first upper electrode 74A according to the first system transistor 29A is at a distance of 2000 Å or more (preferably, not less than 2500 Å and not more than 4500 Å) from the first principal surface 3 to the bottom wall of the first trench 71A with regard to the depth direction of the first trench 71A. The depth position of the electrode surface of the first upper electrode 74A is adjusted so as to be placed at a depth position at which the characteristic of the gate threshold voltage of the first unit transistor 59A does not decrease.

Similarly, preferably, the electrode surface of the second upper electrode 74B according to the second system transistor 29B is at a distance of 2000 Å or more (preferably, not less than 2500 Å and not more than 4500 Å) from the first principal surface 3 to the bottom wall of the second trench 71B from the first principal surface 3 with regard to the depth direction of the second trench 71B. The depth position of the electrode surface of the second upper electrode 74B is adjusted so as to be placed at a depth position at which the characteristic of the gate threshold voltage of the second unit transistor 59B does not decrease.

The thus formed structures make it possible to bury the first upper electrode 74A in the first trench 71A by appropriately separating the first upper electrode 74A from the second upper electrode 74B, and make it possible to bury the second upper electrode 74B in the second trench 71B by appropriately separating the second upper electrode 74B from the first upper electrode 74A. This makes it possible to appropriately reduce a short circuit risk between the first upper electrode 74A and the second upper electrode 74B. Additionally, the first source region 77A (first channel region 79A) is enabled to appropriately face the first upper electrode 74A, and the second source region 77B (second channel region 79B) is enabled to appropriately face the second upper electrode 74B.

The first unit transistor 59A (in detail, the first channel region 79A) serves as a heat generation source in the first element region 6. Therefore, the number of the first unit transistors 59A determines the amount of heat generation of the single first composite cell 81, and the arrangement of the first composite cells 81 determines the place of heat generation in the first element region 6. In other words, if the number of the first unit transistors 59A that compose the single first composite cell 81 is increased, the amount of heat generation in the single first composite cell 81 increases. Additionally, if the first composite cells 81 are arranged so as to adjoin each other, the place of heat generation in the first element region 6 becomes local.

Therefore, preferably, the number of the first unit transistors 59A is four or less (α≤4). This structure makes it possible to suppress a rise in temperature that occurs locally in the single first composite cell 81. Particularly preferably, the number of the first unit transistors 59A is two (α=2) in consideration of the short circuit risk and the amount of heat generation mentioned above. Preferably, the first composite cells 81 are arrayed at equal intervals in a region between one end portion and the other end portion of the first element region 6. This structure makes it possible to thin out the place of heat generation caused by the first composite cells 81 in the first element region 6, and makes it possible to suppress a rise in temperature that occurs locally in the first element region 6.

Preferably, in each of the first composite cells 81, the first channel regions 79A (first source regions 77A) arrayed on one first trench structure 61A side face a region between the first channel regions 79A (first source regions 77A) arrayed on the other first trench structure 61A side in the first direction X. This structure makes it possible to thin out the starting point of heat generation in each of the first composite cells 81. This makes it possible to suppress a rise in temperature that occurs locally in each of the first composite cells 81.

In this case, preferably, in each of the first unit cells 60A, the first channel regions 79A formed in one of the first channel cells 62A face the first channel regions 79A formed in the other first channel cell 62A across a corresponding one of the first trench structures 61A. Preferably, in each of the first composite cells 81, the first channel regions 79A formed in a region between the pair of first trench structures 61A are arrayed so as to deviate from each other in the second direction Y in a plan view. Of course, in each of the first unit cells 60A, the first channel regions 79A formed in one of the first channel cells 62A may face a region between the first channel regions 79A formed in the other first channel cell 62A across a corresponding one of the first trench structures 61A.

In each of the first unit cells 60A, the first contact regions 78A formed in one of the first channel cells 62A may face the first contact regions 78A formed in the other first channel cell 62A across a corresponding one of the first trench structures 61A. In each of the first composite cells 81, the first contact regions 78A arrayed on one first trench structure 61A side may face a region between the first contact regions 78A arrayed on the other first trench structure 61A side in the first direction X.

In each of the first composite cells 81, the first contact regions 78A formed in a region between the pair of first trench structures 61A may be arrayed so as to deviate from each other in the second direction Y in a plan view. Additionally, the first contact regions 78A may face the first source regions 77A in the first direction X in a plan view.

The second unit transistor 59B serves as a heat generation source in the first element region 6. Therefore, the number of the second unit transistors 59B determines the amount of heat generation of the single second composite cell 82, and the arrangement of the second composite cells 82 determines the place of heat generation in the first element region 6. In other words, if the number of the second unit transistors 59B that compose the single second composite cell 82 is increased, the amount of heat generation in the single second composite cell 82 increases. Additionally, if the second composite cells 82 are arranged so as to adjoin each other, the place of heat generation in the first element region 6 becomes local.

Therefore, preferably, the number of the second unit transistors 59B is four or less (β≤4). This structure makes it possible to suppress a rise in temperature that occurs locally in the single second composite cell 82. In this case, preferably, the number of the second unit transistors 59B is equal to the number of the first unit transistors 59A. This structure makes it possible to suppress a variation in the range of heat generation caused by the first composite cell 81 and a variation in the range of heat generation caused by the second composite cell 82. Particularly preferably, the number of the second unit transistors 59B is two (β=2) in consideration of the short circuit risk and the amount of heat generation mentioned above.

Preferably, the second composite cells 82 are arrayed at equal intervals in a region between one end portion and the other end portion of the first element region 6. This structure makes it possible to thin out the place of heat generation caused by the second composite cells 82 in the first element region 6, and makes it possible to suppress a rise in temperature that occurs locally in the first element region 6. In this case, preferably, at least one second composite cell 82 is disposed adjacently to at least one first composite cell 81. This structure makes it possible to, in the first and second composite cells 81 and 82 adjacent to each other, create a situation in which one of the first and second composite cells 81 and 82 is in an ON state, and the other one thereof is in an OFF state. This makes it possible to suppress a rise in temperature that occurs locally caused by the first and second composite cells 81 and 82.

In this case, preferably, at least one second composite cell 82 is disposed in a region between two first composite cells 81 adjoining each other. Additionally, in this case, particularly preferably, the second composite cells 82 are arrayed alternately with the first composite cells 81 in a manner in which the single first composite cell 81 is interposed between the second composite cells 82. These structures make it possible to separate the mutually-adjacent two first composite cells 81 from each other by the amount of the second composite cell 82. This makes it possible to appropriately thin out the place of heat generation caused by the first composite cells 81 and by the second composite cells 82, and makes it possible to appropriately suppress a rise in temperature that occurs locally in the first element region 6.

Preferably, in each of the second composite cells 82, the second channel regions 79B (second source regions 77B) arrayed on one second trench structure 61B side face a region between the second channel regions 79B (second source regions 77B) arrayed on the other second trench structure 61B side in the first direction X. This structure makes it possible to thin out the starting point of heat generation in each of the second composite cells 82. This makes it possible to suppress a rise in temperature that occurs locally in each of the second composite cells 82.

In this case, preferably, in each of the second unit cells 60B, the second channel regions 79B formed in one of the second channel cells 62B face the second channel regions 79B formed in the other second channel cell 62B across a corresponding one of the second trench structures 61B. Preferably, in each of the second composite cells 82, the second channel regions 79B formed in a region between the pair of second trench structures 61B are arrayed so as to deviate from each other in the second direction Y in a plan view.

Preferably, the second channel regions 79B are arrayed so as to deviate from each other in the second direction Y with respect to the first channel regions 79A in a trench-to-trench region between each of the first trench structures 61A and each of the second trench structures 61B. In other words, preferably, the second channel regions 79B face a region between the first contact regions 78A in the first direction X in the trench-to-trench region. These structures make it possible to thin out the starting point of heat generation in the trench-to-trench region. This makes it possible to suppress a rise in temperature that occurs locally in the trench-to-trench region.

In each of the second unit cells 60B, the second contact regions 78B formed in one of the second channel cells 62B may face the second contact regions 78B formed in the other second channel cell 62B across a corresponding one of the second trench structures 61B. In each of the second composite cells 82, the second contact regions 78B arrayed on one second trench structure 61B side may face a region between the second contact regions 78B arrayed on the other second trench structure 61B side in the first direction X. Of course, in each of the second unit cells 60B, the second channel regions 79B formed in one of the second channel cells 62B may face a region between the second channel regions 79B formed in the other second channel cell 62B across a corresponding one of the second trench structures 61B.

In each of the second composite cells 82, the second contact regions 78B formed in a region between the pair of second trench structures 61B may be arrayed so as to deviate from each other in the second direction Y in a plan view. The second contact regions 78B may face the second source regions 77B in the first direction X in a plan view.

The n-system main transistor 8 has a total channel ratio RT. The total channel ratio RT is a ratio of the total plane area of all of the channel regions 79 in the plane area of all of the channel cells 62. The plane area of each of the channel regions 79 is defined by the plane area of each of the source regions 77. The total channel ratio RT is adjusted within a range of more than 0% and less than 100%. Preferably, the total channel ratio RT is adjusted within a range of not less than 25% and not more than 75%.

The total channel ratio RT is divided into n number of system channel ratios RS by means of n number of system transistors 29. The total channel ratio RT of the 2-system main transistor 8 is an added value (RT=RSA+RSB) of a first system channel ratio RSA of the first system transistor 29A and a second system channel ratio RSB of the second system transistor 29B. The first system channel ratio RSA is a ratio of the total plane area of all of the first channel regions 79A in the total plane area of all of the channel cells 62. The second system channel ratio RSB is a ratio of the total plane area of all of the second channel regions 79B in the total plane area of all of the channel cells 62.

The plane area of each of the first channel regions 79A is defined by the plane area of each of the first source regions 77A, and the plane area of each of the second channel regions 79B is defined by the plane area of each of the second source regions 77B. The first system channel ratio RSA is adjusted by an arrayed pattern of both the first source region 77A and the first contact region 78A. The second system channel ratio RSB is adjusted by an arrayed pattern of both the second source region 77B and the second contact region 78B.

The first system channel ratio RSA is divided into a plurality of first channel ratios RCA by means of the first composite cells 81. The first channel ratio RCA is a ratio of the total plane area of the first channel regions 79A in the total plane area of all of the channel cells 62 in each of the first composite cells 81. The first system channel ratio RSA is an added value of the first channel ratios RCA. Preferably, the first composite cells 81 have first channel ratios RCA equal to each other. In each of the first unit transistors 59A, the first channel regions 79A may be formed with first areas that are different from each other or that are equal to each other per unit area.

The second system channel ratio RSB is divided into a plurality of second channel ratios RCB. The second channel ratio RCB is a ratio of the total plane area of the second channel regions 79B in the total plane area of all of the channel cells 62 in each of the second composite cells 82. The second composite cells 82 have an added value of the second channel ratios RCB. Preferably, the second composite cells 82 have second channel ratios RCB that are equal to each other. In each of the second unit transistors 59B, the second channel regions 79B may be formed with second areas that are different from each other or that are equal to each other per unit area. The second area may be equal to or be different from the first area of the first channel regions 79A per unit area.

The second system channel ratio RSB may be substantially equal to the first system channel ratio RSA (RSA≈RSB). The second system channel ratio RSB may exceed the first system channel ratio RSA (RSA<RSB). The second system channel ratio RSB may be less than the first system channel ratio RSA (RSB<RSA).

The main transistor 8 includes a plurality of pairs (in this preferred embodiment, four pairs and, in total, eight) first trench connection structures 90 formed at the first principal surface 3 in the first element region 6. Each of the pairs of first trench connection structures 90 includes the first trench connection structure 90 on one side (the first peripheral end surface 5A side) and the first trench connection structure 90 on the other side (the second peripheral end surface 5B side) that face each other across a corresponding one of the first composite cells 81 with regard to the second direction Y.

The first trench connection structure 90 on the one side connects the first end portions 63 of the plurality of (in this preferred embodiment, one pair of) first trench structures 61A in an arched shape in a plan view. The first trench connection structure 90 on the other side connects the second end portions 64 of the plurality of (in this preferred embodiment, one pair of) first trench structures 61A in an arched shape in a plan view. The pair of first trench connection structures 90 compose a single annular trench structure together with the plurality of (in this preferred embodiment, one pair of) first trench structures 61A that are constituents of the single first composite cell 81.

The first trench connection structure 90 on the other side has the same structure as the first trench connection structure 90 on the one side, except that the first trench connection structure 90 on the other side is connected to the second end portion 64 of the first trench structure 61A. A configuration of the first trench connection structure 90 on the one side is hereinafter described, and a description of a configuration of the first trench connection structure 90 on the other side is omitted.

The first trench connection structure 90 on the one side has a first part 90A extending in the first direction X and a plurality of (in this preferred embodiment, a pair of) second parts 90B extending in the second direction Y. The first part 90A faces the first end portions 63 in a plan view. The second parts 90B extend from the first part 90A toward the first end portions 63, and are connected to these first end portions 63.

The first trench connection structure 90 on the one side has a connection width WC and a connection depth DC. The connection width WC is a width in a direction perpendicular to a direction in which the first trench connection structure 90 extends. Preferably, the connection width WC is substantially equal to the trench width W of the trench structure 61 (WC≈W). Preferably, the connection depth DC is substantially equal to the trench depth D of the trench structure 61 (DC≈D). Preferably, an aspect ratio DC/WC of the first trench connection structure 90 is substantially equal to the aspect ratio D/W of the trench structure 61 (DC/WC≈D/W). Preferably, the bottom wall of the first trench connection structure 90 is at a distance of not less than 1 μm and not more than 5 μm from the bottom portion of the second semiconductor region 52.

The first trench connection structure 90 on the one side has a single electrode structure including a first connection trench 91, a first connection insulating film 92, a first connection electrode 93, and a first cap insulating film 94. The first connection trench 91 extends in an arched shape so as to communicate with the first end portions 63 of the first trenches 71A in a plan view, and is dug down from the first principal surface 3 toward the second principal surface 4. The first connection trench 91 divisionally forms the first part 90A and the second part 90B of the first trench connection structure 90. The first connection trench 91 is formed at a distance from the bottom portion of the second semiconductor region 52 toward the first principal surface 3 side.

The first connection trench 91 includes a sidewall and a bottom wall. The angle of the sidewall of the first connection trench 91 with the first principal surface 3 in the semiconductor chip 2 may be not less than 90° and not more than 92°. The first connection trench 91 may be formed in a tapered shape in which the opening width becomes smaller from its opening toward its bottom wall. Preferably, a corner portion of the bottom wall of the first connection trench 91 is formed in a curved shape. The entirety of the bottom wall of the first connection trench 91 may be formed so as to be curved toward the second principal surface 4. The sidewall and the bottom wall of the first connection trench 91 are smoothly connected to the sidewall and the bottom wall of the first trench 71A.

The first connection insulating film 92 is formed on a wall surface of the first connection trench 91. In detail, the first connection insulating film 92 is formed as a film in the whole area of the wall surface of the first connection trench 91, and divisionally forms a recessed space in the first connection trench 91. The first connection insulating film 92 extends in the first direction X in the first part 90A of the first connection trench 91. The first connection insulating film 92 extends in the second direction Y in the second part 90B of the first connection trench 91. The first connection insulating film 92 is connected to the first upper insulating film 72A and to the first lower insulating film 73A in a communication portion between the first connection trench 91 and the first trench 71A. The first connection insulating film 92 includes a silicon oxide film. Particularly preferably, the first connection insulating film 92 includes a silicon oxide film constituted of an oxide of the semiconductor chip 2.

The first connection insulating film 92 has a third thickness T3. The third thickness T3 is a thickness along the normal direction of the wall surface of the first connection trench 91. The third thickness T3 exceeds the first thickness T1 of the first upper insulating film 72A (T1<T3). The third thickness T3 may be substantially equal to the second thickness T2 of the lower insulating film 73 (T2≈T3). The third thickness T3 may be substantially equal to the separation thickness TI of the separation insulating film 55 (T3≈TI). The third thickness T3 may be not less than 0.1 μm and not more than 1 μm. Preferably, the third thickness T3 is not less than 0.15 μm and not more than 0.65 μm. The thickness of a part, which covers the bottom wall of the first connection trench 91, of the first connection insulating film 92 may be less than the thickness of a part, which covers the sidewall of the first connection trench 91, of the first connection insulating film 92.

The first connection electrode 93 is embedded in the first connection trench 91 as an integrated member with the first connection insulating film 92 between the first connection electrode 93 and the first connection trench 91. In this preferred embodiment, the first connection electrode 93 includes conductive polysilicon. The first connection electrode 93 extends in the first direction X in the first part 90A of the first connection trench 91. The first connection electrode 93 extends in the second direction Y in the second part 90B of the first connection trench 91. The first connection electrode 93 is connected to the first lower electrode 75A in the communication portion between the first connection trench 91 and the first trench 71A.

The first connection electrode 93 is electrically insulated from the first upper electrode 74A with the first intermediate insulating film 76A between the first connection electrode 93 and the first upper electrode 74A. In other words, the first connection electrode 93 is constituted of a lead-out portion led out from the first trench 71A toward the first connection trench 91 across both the first connection insulating film 92 and the first intermediate insulating film 76A in the first lower electrode 75A. The first gate signal G1 is transmitted to the first lower electrode 75A through the first connection electrode 93. In other words, the same first gate signal G1 is applied to the first connection electrode 93 simultaneously with the first upper electrode 74A.

The first connection electrode 93 has an electrode surface (first connection electrode surface) exposed from the first connection trench 91. The electrode surface of the first connection electrode 93 may be hollowed so as to be curved toward the bottom wall of the first connection trench 91. Preferably, the electrode surface of the first connection electrode 93 is located (projected) closer to the first principal surface 3 than the depth position of the electrode surface of the upper electrode 74 of the trench structure 61 with regard to the depth direction of the first connection trench 91. Preferably, the electrode surface of the first connection electrode 93 is at a distance of not less than 0 Å and less than 2000 Å from the first principal surface 3 to the bottom wall of the first connection trench 91. Particularly preferably, the electrode surface of the first connection electrode 93 is at a distance of less than 1000 Å from the first principal surface 3 to the bottom wall of the first connection trench 91.

The first cap insulating film 94 covers the electrode surface of the first connection electrode 93 in the first connection trench 91 as a film. The first cap insulating film 94 suppresses a short circuit of the first connection electrode 93 with another electrode. The first cap insulating film 94 is continuous with the first connection insulating film 92. Preferably, the first cap insulating film 94 includes a silicon oxide film. Particularly preferably, the first cap insulating film 94 includes a silicon oxide film constituted of an oxide of the first connection electrode 93. In other words, preferably, the first cap insulating film 94 includes an oxide of polysilicon, and the first connection insulating film 92 includes an oxide of a silicon monocrystal.

The main transistor 8 includes a plurality of pairs (in this preferred embodiment, four pairs of, and, in total, eight) second trench connection structures 100 formed at the first principal surface 3 in the first element region 6. Each of the pairs of second trench connection structures 100 includes the second trench connection structure 100 on one side (on the first peripheral end surface 5A side) and the second trench connection structure 100 on the other side (on the second peripheral end surface 5B side) that face each other across a corresponding one of the second composite cells 82 with regard to the second direction Y.

The second trench connection structure 100 on the one side connects the first end portions 63 of the plurality of (in this preferred embodiment, the pair of) second trench structures 61B in an arched shape in a plan view. The second trench connection structure 100 on the other side connects the second end portions 64 of the plurality of (in this preferred embodiment, the pair of) second trench structures 61B in an arched shape in a plan view. The pair of second trench connection structures 100 compose a single annular trench structure together with the plurality of (in this preferred embodiment, the pair of) second trench structures 61B that are constituents of the single second composite cell 82.

The second trench connection structure 100 on the other side has the same structure as the second trench connection structure 100 on the one side, except that the second trench connection structure 100 on the other side is connected to the second end portion 64 of the second trench structure 61B. A configuration of the second trench connection structure 100 on the one side is hereinafter described, and a description of a configuration of the second trench connection structure 100 on the other side is omitted.

The second trench connection structure 100 on the one side has a first part 100A extending in the first direction X and a plurality of (in this preferred embodiment, a pair of) second parts 100B extending in the second direction Y. The first part 100A faces the first end portions 63 in a plan view. The second parts 100B extend from the first part 100A toward the first end portions 63, and are connected to these first end portions 63. The second trench connection structure 100 on the one side has the connection width WC and the connection depth DC in the same way as each of the first trench connection structures 90.

The second trench connection structure 100 on the one side has a single electrode structure including a second connection trench 101, a second connection insulating film 102, a second connection electrode 103, and a second cap insulating film 104. The second connection trench 101 extends in an arched shape so as to communicate with the first end portions 63 of the pair of second trenches 71B in a plan view, and is dug down from the first principal surface 3 toward the second principal surface 4. The second connection trench 101 divisionally forms the first part 100A and the second part 100B of the second trench connection structure 100. The second connection trench 101 is formed at a distance from the bottom portion of the second semiconductor region 52 toward the first principal surface 3 side.

The second connection trench 101 includes a sidewall and a bottom wall. The angle of the sidewall of the second connection trench 101 with the first principal surface 3 in the semiconductor chip 2 may be not less than 90° and not more than 92°. The second connection trench 101 may be formed in a tapered shape in which the opening width becomes smaller from its opening toward its bottom wall. Preferably, a corner portion of the bottom wall of the second connection trench 101 is formed in a curved shape. The entirety of the bottom wall of the second connection trench 101 may be formed so as to be curved toward the second principal surface 4. The sidewall and the bottom wall of the second connection trench 101 are smoothly connected to the sidewall and the bottom wall of the second trench 71B.

The second connection insulating film 102 is formed on a wall surface of the second connection trench 101. In detail, the second connection insulating film 102 is formed as a film in the whole area of the wall surface of the second connection trench 101, and divisionally forms a recessed space in the second connection trench 101. The second connection insulating film 102 extends in the first direction X in the first part 100A of the second connection trench 101. The second connection insulating film 102 extends in the second direction Y in the second part 100B of the second connection trench 101. The second connection insulating film 102 includes a silicon oxide film. Particularly preferably, the second connection insulating film 102 includes a silicon oxide film constituted of an oxide of the semiconductor chip 2. The second connection insulating film 102 has the third thickness T3 in the same way as the first connection insulating film 92.

The second connection electrode 103 is embedded in the second connection trench 101 as an integrated member with the second connection insulating film 102 between the second connection electrode 103 and the second connection trench 101. In this preferred embodiment, the second connection electrode 103 includes conductive polysilicon. The second connection electrode 103 extends in the first direction X in the first part 100A of the second connection trench 101. The second connection electrode 103 extends in the second direction Y in the second part 100B of the second connection trench 101. The second connection electrode 103 is connected to the second lower electrode 75B in the communication portion between the second connection trench 101 and the second trench 71B.

The second connection electrode 103 is electrically insulated from the second upper electrode 74B with the second intermediate insulating film 76B between the second connection electrode 103 and the second upper electrode 74B. In other words, the second connection electrode 103 is constituted of a lead-out portion led out from the second trench 71B toward the second connection trench 101 across both the second connection insulating film 102 and the second intermediate insulating film 76B in the second lower electrode 75B. The second gate signal G2 is transmitted to the second lower electrode 75B through the second connection electrode 103. In other words, the same second gate signal G2 is applied to the second connection electrode 103 simultaneously with the second upper electrode 74B.

The second connection electrode 103 has an electrode surface (second connection electrode surface) exposed from the second connection trench 101. The electrode surface of the second connection electrode 103 may be hollowed so as to be curved toward the bottom wall of the second connection trench 101. Preferably, the electrode surface of the second connection electrode 103 is located (projected) closer to the first principal surface 3 than the depth position of the electrode surface of the upper electrode 74 of the trench structure 61 with regard to the depth direction of the second connection trench 101. Preferably, the electrode surface of the second connection electrode 103 is at a distance of not less than 0 Å and less than 2000 Å from the first principal surface 3 to the bottom wall of the second connection trench 101. Particularly preferably, the electrode surface of the second connection electrode 103 is at a distance of less than 1000 Å from the first principal surface 3 to the bottom wall of the second connection trench 101.

The second cap insulating film 104 covers the electrode surface (second connection electrode surface) of the second connection electrode 103 in the second connection trench 101 as a film. The second cap insulating film 104 suppresses a short circuit of the second connection electrode 103 with another electrode. The second cap insulating film 104 is continuous with the second connection insulating film 102. Preferably, the second cap insulating film 104 includes a silicon oxide film. Particularly preferably, the second cap insulating film 104 includes a silicon oxide film constituted of an oxide of the second connection electrode 103. In other words, preferably, the second cap insulating film 104 includes an oxide of polysilicon, and the second connection insulating film 102 includes an oxide of a silicon monocrystal.

The semiconductor device 1 includes a body space 110 formed along the inner edge (inner peripheral wall) of the trench separation structure 53 in the first element region 6. The body space 110 is formed of a part of the body region 58. The body space 110 is formed in a belt shape extending along the main transistor 8 in a plan view. In detail, the body space 110 is formed in an annular shape surrounding the main transistor 8 in a plan view.

The body space 110 has a space width WSP. The space width WSP may be equal to or more than the separation width WI (WI≤WSP), or may be less than the separation width WI (WSP<WI). Preferably, the body space 110 has a substantially constant space width WSP on the basis of the inner edge of the trench separation structure 53. The space width WSP may be not less than 1 μm and not more than 2.5 μm. Preferably, the space width WSP is not less than 1.2 μm and not more than 2 μm.

The semiconductor device 1 includes a field insulating film 111 that partially covers the first principal surface 3 in the first element region 6. The field insulating film 111 is formed at a distance from the main transistor 8 toward the trench separation structure 53 side in a plan view, and covers the periphery of the trench separation structure 53. In other words, the field insulating film 111 covers the body space 110 (body region 58). The field insulating film 111 faces the second semiconductor region 52 (first semiconductor region 51) across the body space 110 (body region 58) in a peripheral edge portion of the first element region 6. The field insulating film 111 includes a silicon oxide film. Particularly preferably, the field insulating film 111 includes a silicon oxide film constituted of an oxide of the semiconductor chip 2.

The field insulating film 111 is formed in a belt shape extending along an inner edge (inner peripheral wall) of the trench separation structure 53 in a plan view. In this preferred embodiment, the field insulating film 111 is formed in an annular shape extending along the inner peripheral wall of the trench separation structure 53 in a plan view, and surrounds an inward portion of the first element region 6 over its entire periphery. The field insulating film 111 has a side extending in one direction (first direction X) and a side extending in an intersecting direction (second direction Y) that intersects the one direction in a plan view. The field insulating film 111 is continuous with the separation insulating film 55 on the inner edge (inner peripheral wall) side of the trench separation structure 53. The first element region 6 is demarcated by the trench separation structure 53 in the semiconductor chip 2, and is demarcated by the field insulating film 111 on the semiconductor chip 2.

The field insulating film 111 has an insulating sidewall 112 that divisionally forms the inward portion of the first element region 6. The insulating sidewall 112 is formed over the entire periphery of the field insulating film 111. The insulating sidewall 112 has a side extending in one direction (first direction X) and a side extending in an intersecting direction (second direction Y) that intersects the one direction. The insulating sidewall 112 is located on the body space 110 (body region 58). The insulating sidewall 112 is obliquely downwardly inclined so as to make an acute angle with the first principal surface 3. In detail, the insulating sidewall 112 has an upper end portion located on the principal surface side of the field insulating film 111 and a lower end portion located on the first principal surface 3 side, and is obliquely downwardly inclined from the upper end portion toward the lower end portion.

The insulating sidewall 112 makes an inclination angle of not less than 20° and not more than 40° with the first principal surface 3 (20°≤θ≤40°). The inclination angle is an angle (absolute value) that is made by a straight line with respect to the first principal surface 3 inside the field insulating film 111 if the straight line is set as a line that connects the upper end portion and the lower end portion of the insulating sidewall 112 in a cross-sectional view. Preferably, the inclination angle is less than 40° (θ<40°).

Particularly preferably, the inclination angle falls within a range of 30°±6° (24°≤θ≤36°). Typically, the inclination angle falls within a range of not less than 28° and not more than 36° (28°≤θ≤36°). The insulating sidewall 112 may be inclined in a curved shape hollowed toward the first principal surface 3 in a region between the upper end portion and the lower end portion. Similarly, in this case, the inclination angle is an angle (absolute value) that is made by a straight line with respect to the first principal surface 3 if the straight line is set as a line that connects the upper end portion and the lower end portion of the insulating sidewall 112 in a cross-sectional view.

With the insulating sidewall 112 having a comparatively gentle inclination angle, it is possible to suppress electrode residues generated when the trench structure 61 and the like are formed from remaining in a state in which the electrode residues have adhered to the insulating sidewall 112. This makes it possible to reduce a short circuit risk between the unit transistors 59 caused by the electrode residues. Digging down the electrode surface of the first upper electrode 74A and the electrode surface of the second upper electrode 74B more deeply than the electrode surface of the separation electrode 56 or the like is effective for reducing the short circuit risk of the first and second upper electrodes 74A and 74B caused by the electrode residues.

The field insulating film 111 has a thickness exceeding the first thickness T1 of the upper insulating film 72. The thickness of the field insulating film 111 is a thickness along the normal direction Z of parts other than the insulating sidewall 112. Preferably, the thickness of the field insulating film 111 exceeds the intermediate thickness TM of the intermediate insulating film 76. The thickness of the field insulating film 111 may be substantially equal to the second thickness T2 of the lower insulating film 73. The thickness of the field insulating film 111 may be substantially equal to the separation thickness TI of the separation insulating film 55. The thickness of the field insulating film 111 may be not less than 0.1 μm and not more than 1 μm. Preferably, the thickness of the field insulating film 111 is not less than 0.15 μm and not more than 0.65 μm.

The semiconductor device 1 includes a principal surface insulating film 113 that selectively covers the first principal surface 3 in the first element region 6. The principal surface insulating film 113 includes a silicon oxide film. Particularly preferably, the principal surface insulating film 113 includes a silicon oxide film constituted of an oxide of the semiconductor chip 2. The principal surface insulating film 113 covers the trench structure 61, the first trench connection structure 90, the second trench connection structure 100, and a region located outside the field insulating film 111 in the first principal surface 3, and is continuous with the upper insulating film 72, the first connection insulating film 92, the second connection insulating film 102, and the field insulating film 111 (insulating sidewall 112).

The principal surface insulating film 113 has a thickness less than the thickness of the field insulating film 111. Preferably, the thickness of the principal surface insulating film 113 is equal to or less than ⅕ of the thickness of the field insulating film 111. The thickness of the principal surface insulating film 113 may be substantially equal to the first thickness T1 of the upper insulating film 72. The thickness of the principal surface insulating film 113 may be not less than 0.01 μm and not more than 0.05 μm. Preferably, the thickness of the principal surface insulating film 113 is not less than 0.02 μm and not more than 0.04 μm.

The semiconductor device 1 includes the aforementioned interlayer insulating layer 17 covering the first principal surface 3. The semiconductor device 1 includes a plurality of plug electrodes 121 to 125 embedded in the interlayer insulating layer 17. The plug electrodes 121 to 125 may include the first connection via 201 and the second connection via 202 of FIG. 2. The plug electrodes 121 to 125 include a plurality of first plug electrodes 121, a plurality of second plug electrodes 122, a plurality of third plug electrodes 123, a plurality of fourth plug electrodes 124, and a plurality of fifth plug electrodes 125. The plug electrodes 121 to 125 may be each constituted of a tungsten plug electrode. In some of the accompanying drawings, the plug electrodes 121 to 125 are each simplified and shown by an X mark or by a line.

The first plug electrodes 121 are each constituted of a source plug electrode for the separation electrode 56. The first plug electrodes 121 are each embedded in a part, which covers the trench separation structure 53, of the interlayer insulating layer 17. The first plug electrodes 121 are embedded at a distance from each other along the separation electrode 56, and are each electrically connected to the separation electrode 56. The arrangement and the shape of the first plug electrodes 121 are arbitrary. A single or a plurality of first plug electrodes 121 extending in a belt shape or in an annular shape may be formed on the separation electrode 56 in a plan view.

The second plug electrodes 122 are each constituted of a gate plug electrode for the upper electrodes 74. The second plug electrodes 122 are each embedded in a part, which covers the trench structures 61, of the interlayer insulating layer 17. In this preferred embodiment, the second plug electrodes 122 are electrically connected to both end portions of the upper electrodes 74, respectively. The arrangement and the shape of the second plug electrodes 122 are arbitrary. A single or a plurality of second plug electrodes 122 extending in a belt shape along the upper electrode 74 in a plan view may be formed on each of the upper electrodes 74.

The third plug electrodes 123 are each constituted of a source plug electrode for the channel cell 62. The third plug electrodes 123 are each embedded in a part, which covers the source regions 77 and the contact regions 78, of the interlayer insulating layer 17. The third plug electrodes 123 are each electrically connected to the channel cell 62. The arrangement and the shape of the third plug electrodes 123 are arbitrary.

The fourth plug electrodes 124 are each constituted of a source plug electrode for the outermost contact regions 78. The fourth plug electrodes 124 are each embedded in a part, which covers the outermost contact regions 78 in the interlayer insulating layer 17. The fourth plug electrodes 124 are each embedded at a distance from each other along each of the outermost contact regions 78, and are each electrically connected to each of the outermost contact regions 78. The arrangement and the shape of the fourth plug electrodes 124 are arbitrary. A single or a plurality of fourth plug electrodes 124 extending in a belt shape along the outermost contact region 78 in a plan view may be formed on each of the outermost contact regions 78.

The fifth plug electrodes 125 are each constituted of a gate plug electrode for the first connection electrodes 93 and the second connection electrodes 103. The fifth plug electrodes 125 are embedded in a part, which covers the first connection electrodes 93 and the second connection electrodes 103, of the interlayer insulating layer 17. Each of the fifth plug electrodes 125 is electrically connected to the first connection electrodes 93 and the second connection electrodes 103, respectively. The arrangement and the shape of the fifth plug electrodes 125 are arbitrary. A single or a plurality of fifth plug electrodes 125 extending in a belt shape along the first connection electrodes 93 and the second connection electrodes 103 in a plan view may be formed on the first connection electrodes 93 and the second connection electrodes 103.

The semiconductor device 1 includes a single or a plurality of source wirings 126 disposed in the interlayer insulating layer 17 (see FIG. 6, FIG. 8, and FIG. 9). The source wiring 126 may include the first wiring layer 191 and the second wiring layer 192 of FIG. 2. In other words, a single or a plurality of source wirings 126 are constituted of a wiring layer formed in the interlayer insulating layer 17. The single or the plurality of source wirings 126 are selectively routed around in the interlayer insulating layer 17, and are electrically connected to the separation electrode 56 through the first plug electrodes 121 (first connection via 201), and are electrically connected to the source region 77 and to the contact region 78 through the third plug electrodes 123 (first connection via 201) and through the fourth plug electrodes 124 (first connection via 201). The single or the plurality of source wirings 126 are exposed from the pad opening 28 as the pad 27, and are electrically connected to the aforementioned source terminal 11.

The semiconductor device 1 includes number of the gate wirings 30 as mentioned above and that are formed in the interlayer insulating layer 17. The gate wiring 30 may include the first wiring layer 191 of FIG. 2. The n number of the gate wirings 30 are selectively routed around in the interlayer insulating layer 17. The n number of the gate wirings 30 are each electrically connected to the single or the plurality of trench structures 61 (unit transistor 59) that are to be systematized as to-be-individually-controlled components in the first element region 6, and are electrically connected to the aforementioned control IC 9 in the second element region 7.

In this preferred embodiment, the n number of the gate wirings 30 include a first gate wiring 30A and a second gate wiring 30B. The first gate wiring 30A is electrically connected to the first upper electrode 74A, to the first lower electrode 75A, and to the first connection electrode 93 through a corresponding one of the second plug electrodes 122 and through a corresponding one of the fifth plug electrodes 125, and gives the first gate signal G1 thereto. The second gate wiring 30B is electrically connected to the second upper electrode 74B, to the second lower electrode 75B, and to the second connection electrode 103 through a corresponding one of the second plug electrodes 122 and through a corresponding one of the fifth plug electrodes 125, and gives the second gate signal G2 thereto.

### [Detailed Description of Inspection Wiring 23]

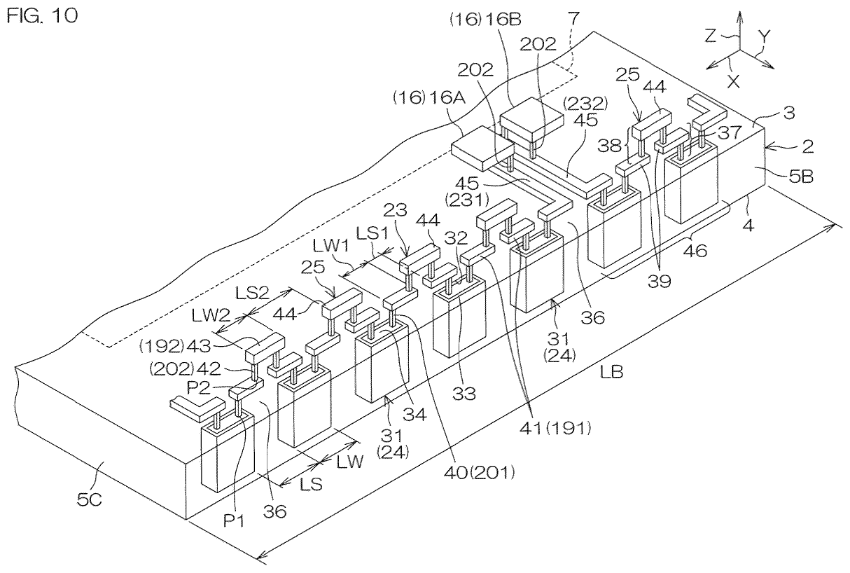

FIG. 10 is an enlarged perspective view of a main portion of the semiconductor device 1, and is a reference view shown to describe a structure of the inspection wiring 23 in detail. Next, the structure of the inspection wiring 23 will be described in detail with reference to FIG. 10 in addition to FIGS. 3 to 9.

Referring to FIG. 3, the inspection wiring 23 surrounds the first element region 6 in a plan view. The inspection wiring 23 is formed at a distance outwardly from the trench separation structure 53 that divisionally forms the first element region 6.

Referring to FIGS. 4 to 7 and FIG. 10, the inspection wiring 23 includes the internal wiring portion 24 and the extending wiring portion 25. As described above, the internal wiring portion 24 is formed at the surficial portion of the first principal surface 3 of the semiconductor chip 2, and the extending wiring portion 25 is formed on the first principal surface 3 of the semiconductor chip 2.

The internal wiring portions 24 are arrayed at a distance from each other along the first to fourth peripheral end surfaces 5A to 5D of the semiconductor chip 2. Only the plurality of (in FIG. 10, seven) internal wiring portions 24 arrayed linearly along the second peripheral end surface 5B are shown in FIG. 10, and yet the internal wiring portions 24 are linearly arrayed in the same way as near the first peripheral end surface 5A, the third peripheral end surface 5C, and the fourth peripheral end surface 5D. Hence, the internal wiring portions 24 are arrayed in an annular shape as a whole along the first to fourth peripheral end surfaces 5A to 5D of the semiconductor chip 2.

In this preferred embodiment, each of the internal wiring portions 24 includes a trench wiring structure 31. The trench wiring structure 31 may be referred to as a “DTI (deep trench isolation) structure,” or may be referred to as a “Second DTI structure” so as to be distinguished from the trench separation structure 53.

The trench wiring structure 31 has a wiring width WW (see FIG. 4 and FIG. 5) and a wiring depth DW (see FIG. 6 and FIG. 7) that are the same as the separation width WI and the separation depth DI of the trench separation structure 53, respectively. The wiring width WW is a width in a direction perpendicular to a direction in which the trench wiring structure 31 extends in a plan view. The wiring width WW may be not less than 0.5 μm and not more than 2.5 μm. Preferably, the wiring width WW is not less than 1.2 μm and not more than 2 μm. The wiring depth DW may be not less than 1 μm and not more than 10 μm. Preferably, the wiring depth DW is not less than 2 μm and not more than 6 μm.

An aspect ratio DW/WW of the trench wiring structure 31 may be more than 1 and not more than 5. The aspect ratio DW/WW is a ratio of the wiring depth DW to the wiring width WW. Preferably, the aspect ratio DW/WW is 2 or more. Preferably, the bottom wall of the trench wiring structure 31 is at a distance of not less than 1 μm and not more than 5 μm from the bottom portion of the second semiconductor region 52.

The trench wiring structure 31 has a corner portion that connects a part extending in the first direction X and a part extending in the second direction Y in a circular arc shape (curved shape). In this preferred embodiment, four corners of the trench wiring structure 31 are each formed in a circular arc shape. Preferably, the corner portion of the trench wiring structure 31 has a constant wiring width WW along the circular arc direction.

Referring to FIG. 10, the trench wiring structure 31 has an internal wiring length LW. The internal wiring length LW is a length in a direction along the first to fourth peripheral end surfaces 5A to 5D (in this preferred embodiment, in a direction parallel to the first to fourth peripheral end surfaces 5A to 5D) in a plan view. The internal wiring length LW may be not less than 2.0 μm and not more than 8.0 μm. Preferably, the internal wiring length LW is not less than 4.0 μm and not more than 6.0 μm. Additionally, the sum of the internal wiring lengths LW in each of the peripheral end surfaces 5A to 5D (total length LT of the internal wiring portion 24 (LW×number of the internal wiring portions 24)) may be not less than 50% and not more than 75% with respect to the length of each of the peripheral end surfaces 5A to 5D (in FIG. 10, length LB of the second peripheral end surface 5B). Preferably, the total length LT is not less than 65% and not more than 75% with respect to the length LB.

Additionally, the interval between the internal wiring portions 24 adjoining each other may be a part of the semiconductor region of the semiconductor chip 2. In this preferred embodiment, the interval between the internal wiring portions 24 adjoining each other is a non-wiring region 36 formed of a part of the second semiconductor region 52. The length of the non-wiring region 36 (length LS of a space between the internal wiring portions 24) may be not less than 1.0 μm and not more than 5.0 μm. Preferably, the length LS is not less than 2.0 μm and not more than 4.0 μm. Additionally, the sum of the lengths LS in each of the peripheral end surfaces 5A to 5D (total length LTS of the non-wiring region 36) may be not less than 25% and not more than 50% with respect to the length of each of the peripheral end surfaces 5A to 5D (in FIG. 10, length LB of the second peripheral end surface 5B). Preferably, the total length LTS is not less than 25% and not more than 35% with respect to the length LB.

The trench wiring structure 31 has a single electrode structure including a wiring trench 32, a wiring insulating film 33 (wiring insulating layer), a wiring electrode 34 (wiring conductive layer), and a wiring cap insulating film 35. The wiring trench 32 is dug down from the first principal surface 3 toward the second principal surface 4. The wiring trench 32 is formed at a distance from the bottom portion of the second semiconductor region 52 toward the first principal surface 3 side.

The wiring trench 32 includes a sidewall and a bottom wall. The angle of the sidewall of the wiring trench 32 with the first principal surface 3 in the semiconductor chip 2 may be not less than 90° and not more than 92°. The wiring trench 32 may be formed in a tapered shape in which an opening width becomes smaller from its opening toward its bottom wall. Preferably, the corner portion of the bottom wall of the wiring trench 32 is formed in a curved shape. The entirety of the bottom wall of the wiring trench 32 may be formed so as to be curved toward the second principal surface 4.

The wiring insulating film 33 is formed on a wall surface of the wiring trench 32. In detail, the wiring insulating film 33 is formed as a film in the whole area of the wall surface of the wiring trench 32, and divisionally forms a recessed space in the wiring trench 32. Preferably, the wiring insulating film 33 includes a silicon oxide film. Particularly preferably, the wiring insulating film 33 includes a silicon oxide film constituted of an oxide of the semiconductor chip 2.

The wiring insulating film 33 has a thickness TW that is same as the separation thickness TI of the separation insulating film 55. The thickness TW is a thickness along the normal direction of the wall surface of the wiring trench 32. The thickness TW may be not less than 0.1 μm and not more than 1 μm. Preferably, the thickness TW is not less than 0.15 μm and not more than 0.65 μm. The thickness of a part, which covers the bottom wall of the wiring trench 32, of the wiring insulating film 33 may be less than the thickness of a part, which covers the sidewall of the wiring trench 32, of the wiring insulating film 33.

The wiring electrode 34 is embedded in the wiring trench 32 as an integrated member with the wiring insulating film 33 between the wiring electrode 34 and the wiring trench 32. In this preferred embodiment, the wiring electrode 34 includes conductive polysilicon. The wiring electrode 34 has an electrode surface (wiring electrode surface) exposed from the wiring trench 32. The electrode surface of the wiring electrode 34 may be hollowed so as to be curved toward the bottom wall of the wiring trench 32. Preferably, the electrode surface of the wiring electrode 34 is at a distance of not less than 0 Å and less than 2000 Å from the first principal surface 3 to the bottom wall of the wiring trench 32 with regard to the depth direction of the wiring trench 32. Particularly preferably, the electrode surface of the wiring electrode 34 is at a distance of less than 1000 Å from the first principal surface 3 to the bottom wall of the wiring trench 32.

The wiring cap insulating film 35 covers the electrode surface of the wiring electrode 34 in the wiring trench 32 as a film. The wiring cap insulating film 35 suppresses a short circuit of the wiring electrode 34 with another electrode. The wiring cap insulating film 35 is continuous with the wiring insulating film 33. Preferably, the wiring cap insulating film 35 includes a silicon oxide film. Particularly preferably, the wiring cap insulating film 35 includes a silicon oxide film constituted of an oxide of the wiring electrode 34. In other words, preferably, the wiring cap insulating film 35 includes an oxide of polysilicon, and the wiring insulating film 33 includes an oxide of a silicon monocrystal.

The extending wiring portion 25 is provided between the internal wiring portions 24 adjoining each other. Referring to, for example, FIG. 10, the extending wiring portion 25 may be formed so that end portions of the extending wiring portion 25 are connected to one of the pair of internal wiring portions 24 adjoining each other and the other internal wiring portion 24, respectively, and may be formed in an arched shape that swells perpendicularly upwardly (toward the side opposite to the first principal surface 3). More specifically, the extending wiring portion 25 may include a first stepped portion 37 that extends in a direction in which one of the pair of internal wiring portions 24 adjoining each other and the other internal wiring portion 24 approach each other from each other and a convex second stepped portion 38 that connects forward end portions 39 of the first stepped portion 37.

In this preferred embodiment, the first stepped portion 37 includes a first longitudinal wiring portion 40 and a first lateral wiring portion 41. The first longitudinal wiring portion 40 and the first lateral wiring portion 41 are each formed by the first connection via 201 and the first wiring layer 191. A lower end portion of the first longitudinal wiring portion 40 is connected to an end portion of the internal wiring portion 24 (in this preferred embodiment, end portion in the longitudinal direction of the wiring electrode 34). The connection position of the first longitudinal wiring portion 40 (first connection via 201) may be a first position P1 in the direction along the first to fourth peripheral end surfaces 5A to 5D.

The first lateral wiring portion 41 horizontally extends from an upper end portion of the first longitudinal wiring portion 40 in a direction in which the first lateral wiring portion 41 approaches the adjacent internal wiring portion 24 so as to overlap with the non-wiring region 36. For example, on the basis of the single internal wiring portion 24, the first lateral wiring portion 41 may be defined as an outward extension portion that extends outwardly from the internal wiring portion 24 and that overlaps with the non-wiring region 36.

The first lateral wiring portion 41 has a first wiring length LW1. The first wiring length LW1 is a length in a direction along the first to fourth peripheral end surfaces 5A to 5D (in this preferred embodiment, in a direction parallel to the first to fourth peripheral end surfaces 5A to 5D) in a plan view. The first wiring length LW1 may be 2.1 μm or more. Additionally, the sum of the first wiring lengths LW1 in each of the peripheral end surfaces 5A to 5D (total length LT1 of the first lateral wiring portion 41 (LW1×number of the first lateral wiring portions 41)) may be not less than 50% and not more than 75% with respect to the length of each of the peripheral end surfaces 5A to 5D (in FIG. 10, length LB of the second peripheral end surface 5B). Preferably, the total length LT1 is not less than 65% and not more than 75% with respect to the length LB.

Additionally, the length between the first lateral wiring portions 41 adjoining each other above the non-wiring region 36 (length LS1 of a space between the first lateral wiring portions 41) may be 0.5 μm or more. Additionally, the sum of the lengths LS1 in each of the peripheral end surfaces 5A to 5D (total length LTS1) may be not less than 25% and not more than 50% with respect to the length of each of the peripheral end surfaces 5A to 5D (in FIG. 10, length LB of the second peripheral end surface 5B). Preferably, the total length LTS1 is not less than 25% and not more than 35% with respect to the length LB.

In this preferred embodiment, the second stepped portion 38 includes a second longitudinal wiring portion 42 and a second lateral wiring portion 43. The second longitudinal wiring portion 42 and the second lateral wiring portion 43 are formed by the second connection via 202 and the second wiring layer 192, respectively. A lower end portion of the second longitudinal wiring portion 42 is connected to an end portion of the first lateral wiring portion 41 (forward end portion 39 of the first stepped portion 37). The connection position of the second longitudinal wiring portion 42 may be a second position P2 in the direction along the first to fourth peripheral end surfaces 5A to 5D. The second position P2 is a position differing from the first position P1. In other words, the second position P2 deviates with respect to the first position P1 in the normal direction Z of the first principal surface 3. Additionally, the first longitudinal wiring portion 40 is disposed at a position directly on the internal wiring portion 24, whereas the second longitudinal wiring portion 42 is disposed at a position directly on the non-wiring region 36.

The second lateral wiring portion 43 connects the second longitudinal wiring portions 42 that are connected to the pair of first lateral wiring portions 41 facing each other on the non-wiring region 36, and its entirety overlaps with the non-wiring region 36. An end portion 44 in the longitudinal direction of the second lateral wiring portion 43 faces the forward end portion 39 of the first lateral wiring portion 41 in the normal direction Z of the first principal surface 3.

The second lateral wiring portion 43 has a second wiring length LW2. The second wiring length LW2 is a length in a direction along the first to fourth peripheral end surfaces 5A to 5D (in this preferred embodiment, in a direction parallel to the first to fourth peripheral end surfaces 5A to 5D) in a plan view. The second wiring length LW2 is shorter than the length LS of the non-wiring region 36. The second wiring length LW2 may be 2.9 μm or more. Additionally, the sum of the second wiring lengths LW2 in each of the peripheral end surfaces 5A to 5D (total length LT2 of the second lateral wiring portion 43 (LW2×number of the second lateral wiring portions 43)) may be not less than 50% and not more than 75% with respect to the length of each of the peripheral end surfaces 5A to 5D (in FIG. 10, length LB of the second peripheral end surface 5B). Preferably, the total length LT2 is not less than 65% and not more than 75% with respect to the length LB.

Additionally, the length between the second lateral wiring portions 43 adjoining each other (length LS2 of a space between the second lateral wiring portions 43) may be 2.3 μm or more. Additionally, the sum of the lengths LS2 in each of the peripheral end surfaces 5A to 5D (total length LTS2) may be not less than 25% and not more than 50% with respect to the length of each of the peripheral end surfaces 5A to 5D (in FIG. 10, length LB of the second peripheral end surface 5B). Preferably, the total length LTS2 is not less than 25% and not more than 35% with respect to the length LB.

In this preferred embodiment, the internal wiring portion 24 and the extending wiring portion 25 are alternately arrayed along the first to fourth peripheral end surfaces 5A to 5D. In an electrical viewpoint, a lower wiring structure consisting of the internal wiring portion 24 (wiring electrode 34) formed inside the semiconductor chip 2 and an upper wiring structure that is electrically connected to the lower wiring structure and that consists of the extending wiring portion 25 formed outside the semiconductor chip 2 (on the side higher than the first principal surface 3) are alternately continuous along the first to fourth peripheral end surfaces 5A to 5D. Hence, the inspection wiring 23 has a chain structure in which a wiring structure exists in each of the internal side of the semiconductor chip 2 and the side opposite to the internal side with respect to the first principal surface 3 with a constant cycle. Hence, the inspection wiring 23 is formed in which the internal wiring portion 24 (lower wiring structure) and the extending wiring portion 25 (upper wiring structure) are alternately connected in series along the first to fourth peripheral end surfaces 5A to 5D.

Additionally, an inspection wiring unit 46 including the pair of internal wiring portions 24 adjoining each other and the extending wiring portion 25 straddling the pair of internal wiring portions 24 may be defined as being arrayed along the first to fourth peripheral end surfaces 5A to 5D. The internal wiring portion 24 is shared between the inspection wiring units 46 adjoining each other.

A circuit wiring 45 that extends from a part of the extending wiring portion 25 toward the inside of the semiconductor chip 2 is formed. In this preferred embodiment, the circuit wiring 45 is formed by use of the first wiring layer 191. The circuit wiring 45 may be the one end 231 and the other end 232 of the inspection wiring 23. The circuit wiring 45 is electrically connected to the examination terminal 16 through the second connection via 202. It is possible to pass an electric current to the inspection wiring 23 by providing a potential difference between the first examination terminal 16A and the second examination terminal 16B. The circuit wiring 45 is not necessarily required to be connected to the examination terminal 16 of the semiconductor chip 2, and may be electrically connected to, for example, the control IC 9. In this case, it is possible to perform a process from the application of a voltage onto the inspection wiring 23 to the changing of a resistance value by means of the control IC 9.

### [Manufacturing Process of Semiconductor Device 1]

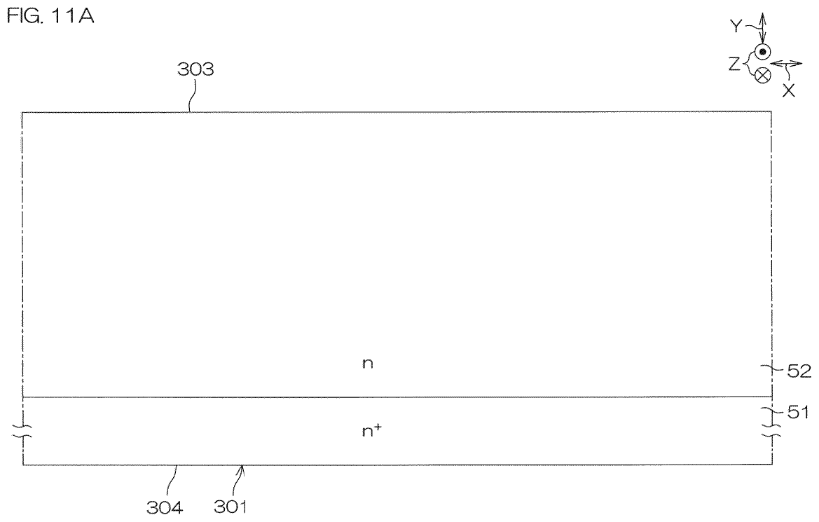

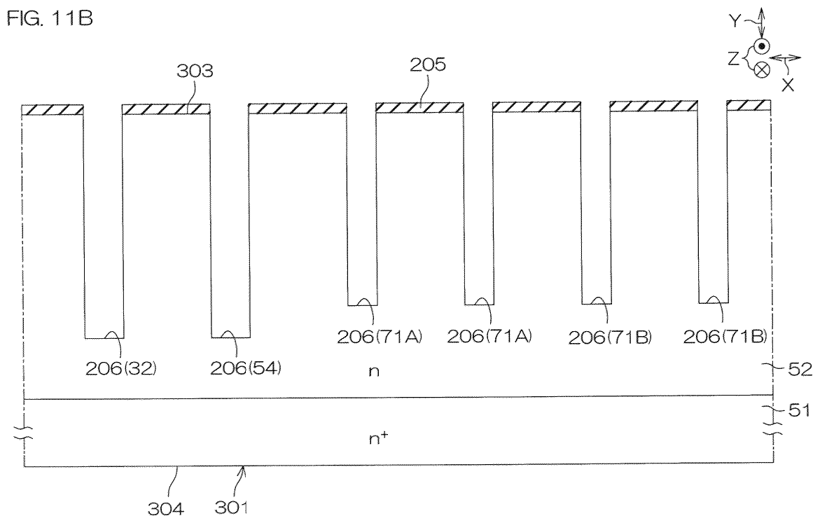

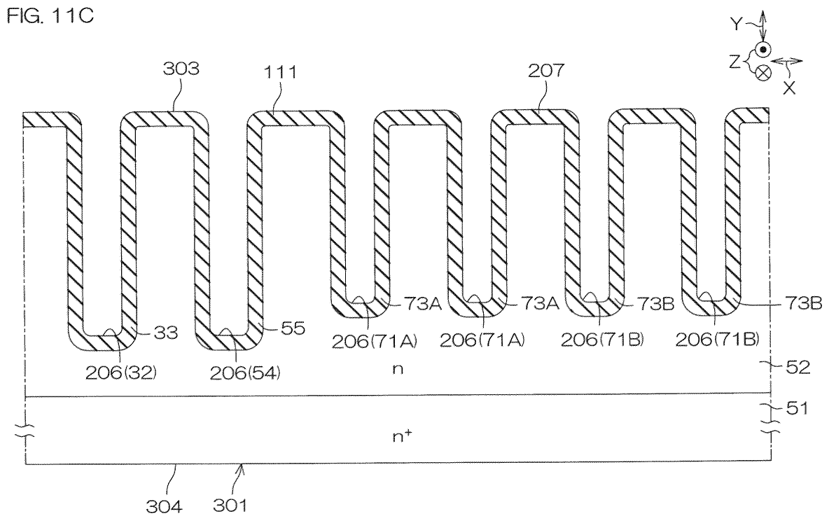

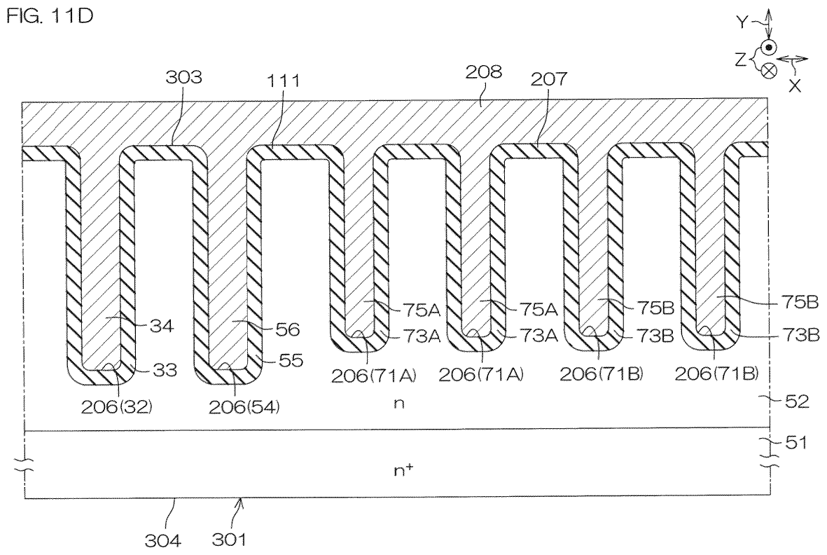

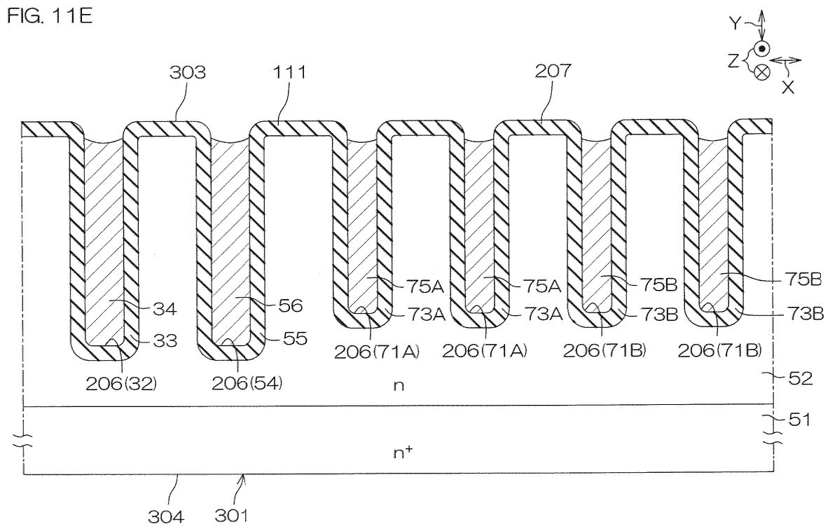

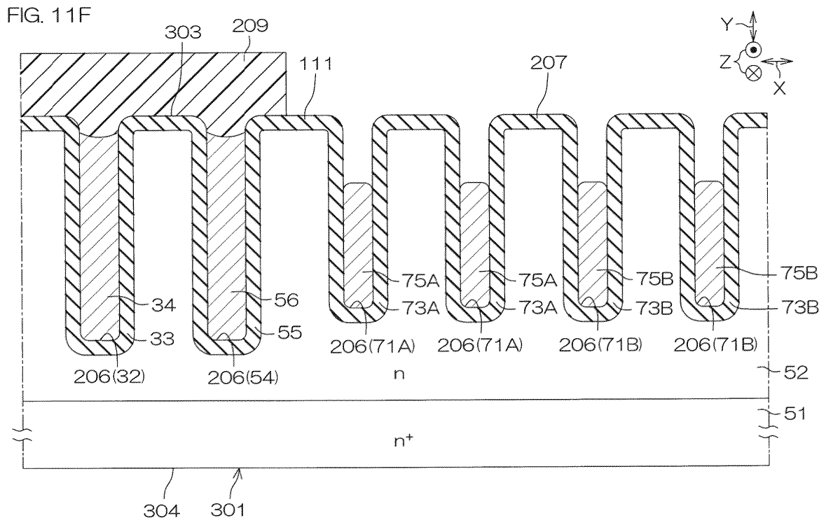

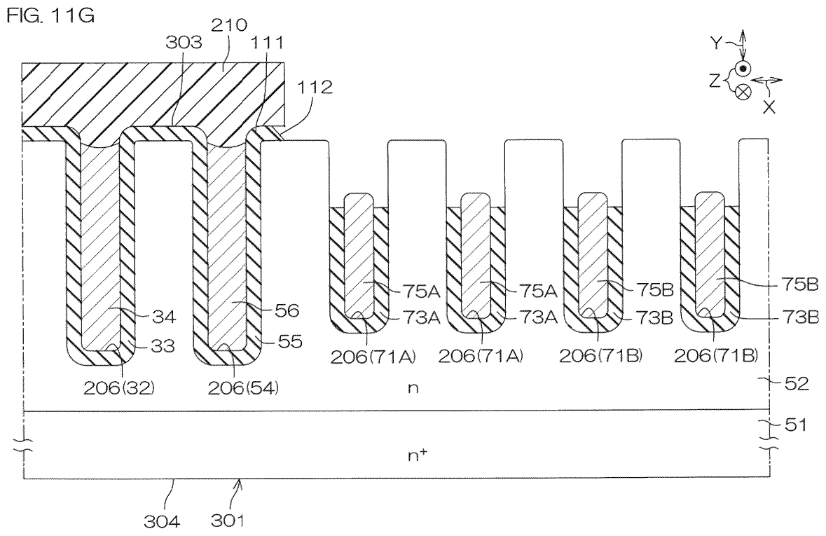

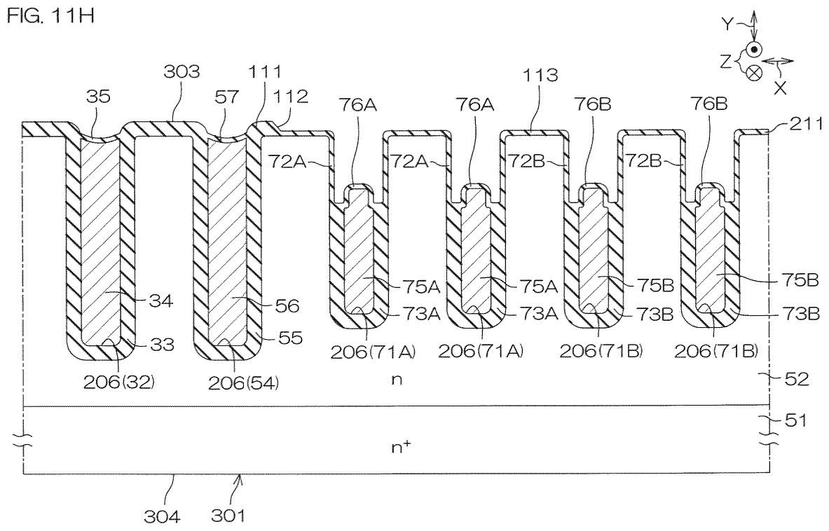

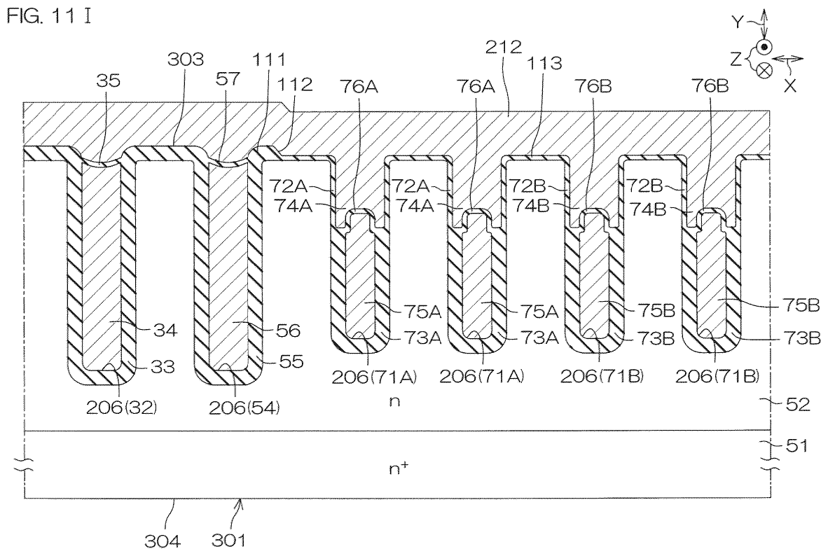

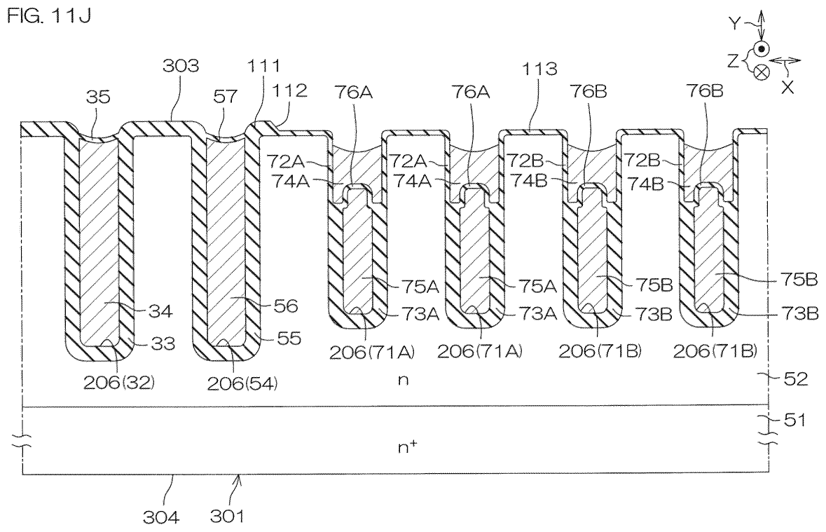

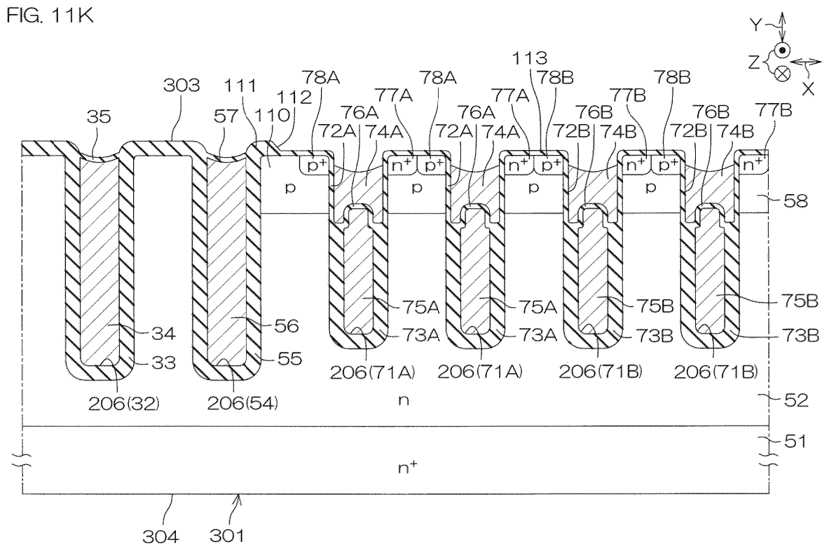

FIG. 11A to FIG. 11K are views each of which shows a part of a manufacturing process of the semiconductor device 1 in the order of process steps. Referring to FIG. 11A, a disk-shaped semiconductor wafer 301 that serves as a base of the semiconductor chip 2 is prepared. The semiconductor wafer 301 has a first wafer principal surface 303 on one side and a second wafer principal surface 304 on the other side. The first wafer principal surface 303 and the second wafer principal surface 304 correspond to the first principal surface 3 and the second principal surface 4 of the semiconductor chip 2, respectively.

The semiconductor wafer 301 has the n-type first semiconductor region 51 at a surficial portion of the second wafer principal surface 304. In this preferred embodiment, the first semiconductor region 51 is constituted of a disk-shaped semiconductor substrate. The semiconductor wafer 301 has the n-type second semiconductor region 52 at a surficial portion of the first wafer principal surface 303. In this preferred embodiment, the second semiconductor region 52 is constituted of an n-type epitaxial layer formed on a principal surface of a semiconductor substrate (first semiconductor region 51) by means of epitaxial growth.

Next, referring to FIG. 11B, a mask 205 having a predetermined pattern is formed on the first wafer main surface 303. In this preferred embodiment, the mask 205 is constituted of an inorganic insulator film (for example, silicon oxide film and/or silicon nitride film). The mask 205 has a pattern corresponding to a plurality of trenches 206. The trenches 206 include the wiring trench 32, the separation trench 54, the first trenches 71A, the second trenches 71B, the first connection trenches 91, and the second connection trenches 101.

Next, unnecessary portions of the semiconductor wafer 301 are removed by an etching method through the mask 205. The etching method may be a wet etching method and/or dry etching method. Preferably, the etching method is an anisotropic dry etching (for example, RIE (Reactive Ion Etching)) method. Hence, the trenches 206 are formed in the first wafer principal surface 303. Thereafter, the mask 205 is removed.

Next, referring to FIG. 11C, a first base insulating film 207 is formed on the first wafer principal surface 303 and on the inner wall of the trenches 206. The first base insulating film 207 serves as a base of the wiring insulating film 33, of the separation insulating film 55, of the first lower insulating films 73A, of the second lower insulating films 73B, of the first connection insulating films 92, of the second connection insulating films 102, and of the field insulating film 111. The first base insulating film 207 includes a silicon oxide film. The first base insulating film 207 may be formed by an oxidation treatment method (for example, thermal oxidation treatment method) and/or a CVD method. In this preferred embodiment, the first base insulating film 207 is formed by the thermal oxidation treatment method.

Next, referring to FIG. 11D, a first base electrode film 208 is formed on the first base insulating film 207. The first base electrode film 208 serves as a base of the wiring electrode 34, of the separation electrode 56, of the first lower electrodes 75A, of the second lower electrodes 75B, of the first connection electrodes 93, and of the second connection electrodes 103. The first base electrode film 208 fills the trenches 206 with the first base insulating film 207 between the first base electrode film 208 and the trenches 206, and covers the first wafer principal surface 303 with the first base insulating film 207 between the first base electrode film 208 and the first wafer principal surface 303. In this preferred embodiment, the first base insulating film 207 is constituted of conductive polysilicon. The first base electrode film 208 may be formed by the CVD method.

Next, referring to FIG. 11E, unnecessary portions of the first base electrode film 208 are removed by the etching method until the first base insulating film 207 is exposed. The etching method may be the wet etching method and/or the dry etching method. Hence, a part of the first base electrode film 208 is embedded in the trenches 206 with the first base insulating film 207 between the part of the first base electrode film 208 and the trenches 206.

Next, referring to FIG. 11F, a first resist mask 209 having a predetermined pattern is formed on the first wafer principal surface 303. The first resist mask 209 exposes regions in which the first lower electrodes 75A and the second lower electrodes 75B are to be formed, and covers regions other than these regions. Next, unnecessary portions of the first base electrode film 208 are removed by the etching method through the first resist mask 209.

The unnecessary portions of the first base electrode film 208 are removed until an electrode surface (etching surface) of the first base electrode film 208 is placed at a halfway portion in the depth direction of the trenches 206. The etching method may be the wet etching method and/or the dry etching method. Hence, the wiring electrode 34, the separation electrode 56, the first lower electrodes 75A, the second lower electrodes 75B, the first connection electrodes 93, and the second connection electrodes 103 are formed. Thereafter, the first resist mask 209 is removed.

Next, referring to FIG. 11G, a second resist mask 210 having a predetermined pattern is formed on the first base electrode film 208. The second resist mask 210 covers regions in which the wiring insulating film 33, the separation insulating film 55, the first connection insulating films 92, the second connection insulating films 102, and the field insulating film 111 are to be formed in the first base insulating film 207, and exposes regions in which the first lower insulating films 73A and the second lower insulating films 73B are to be formed.

Next, unnecessary portions of the first base insulating film 207 are removed by the etching method through the second resist mask 210. The etching method may be the wet etching method and/or the dry etching method. The first base insulating film 207 is removed until an upper end portion of the first lower electrodes 75A and an upper end portion of the second lower electrodes 75B are exposed. Thereafter, the second resist mask 210 is removed.

Next, referring to FIG. 11H, a second base insulating film 211 is formed on the first wafer principal surface 303, on the electrode surface of the separation electrode 56, on an electrode surface of the first lower electrodes 75A, on an electrode surface of the second lower electrodes 75B, and on an inner wall surface of the trenches 206 (trench 71). The second base insulating film 211 includes the wiring cap insulating film 35, the separation cap insulating film 57, the first upper insulating films 72A, the second upper insulating films 72B, the first intermediate insulating films 76A, the second intermediate insulating films 76B, the first cap insulating film 94, the second cap insulating film 104, and the principal surface insulating film 113. In this preferred embodiment, the second base insulating film 211 includes a silicon oxide film. The second base insulating film 211 is formed by the oxidation treatment method (for example, thermal oxidation treatment method) and/or the CVD method. In this preferred embodiment, the second base insulating film 211 is formed by the thermal oxidation treatment method.

Next, referring to FIG. 11I, a second base electrode film 212 is formed on the first wafer principal surface 303. The second base electrode film 212 serves as a base of the first upper electrodes 74A and of the second upper electrodes 74B. The second base electrode film 212 fills the trenches 206 with the second base insulating film 211 between the second base electrode film 212 and the trenches 206, and covers the first wafer principal surface 303 with the second base insulating film 211 between the second base electrode film 212 and the first wafer principal surface 303. In this preferred embodiment, the second base insulating film 211 is constituted of conductive polysilicon. The second base electrode film 212 may be formed by the CVD method.

Next, referring to FIG. 11J, unnecessary portions of the second base electrode film 212 are removed by the etching method until the second base insulating film 211 is exposed. The etching method may be the wet etching method and/or the dry etching method. Hence, a part of the second base electrode film 212 is embedded in the trenches 206 with the second base insulating film 211 between the part of the second base electrode film 212 and the trenches 206, and the first upper electrodes 74A and the second upper electrodes 74B are formed.

Preferably, at this time, an electrode surface (etching surface) of the second base electrode film 212 is formed at a distance of 2000 Å or more from the first wafer principal surface 303 to the bottom wall of the trenches 206 with regard to the depth direction of the trenches 206. Particularly preferably, the electrode surface of the second base electrode film 212 is formed at a distance of not less than 2500 Å and not more than 4500 Å from the first wafer principal surface 303 to the bottom wall of the trenches 206.

According to this step, it is possible to appropriately separate the first upper electrodes 74A from the second upper electrodes 74B and bury the first upper electrodes 74A in the trenches 206 (first trench 71A), and it is possible to appropriately separate the second upper electrodes 74B from the first upper electrodes 74A and bury the second upper electrodes 74B in the trenches 206 (second trench 71B). This makes it possible to appropriately reduce a short circuit risk of the first and second upper electrodes 74A and 74B.

Additionally, according to this step, it is possible to suppress residues of the second base electrode films 212, etc., from remaining in a state in which the residues have adhered to the insulating sidewall 112 of the field insulating film 111. This also makes it possible to reduce a short circuit risk of the first and second upper electrodes 74A and 74B caused by the residues of the second base electrode films 212, etc. The separation cap insulating film 57, the first cap insulating film 94, and the second cap insulating film 104 suppresses a short circuit of the separation electrode 56, the first connection electrode 93, and the second connection electrode 103 with either one or both of the first upper electrode 74A and the second upper electrode 74B because of the residues of the second base electrode films 212, etc.

Next, referring to FIG. 11K, the body region 58, the source region 77, and the contact region 78 are each formed at the surficial portion of the first wafer principal surface 303 according to an ion implantation method through the sidewall of the trenches 206 (trench 71). The body region 58 and the contact region 78 are formed by introducing a p-type impurity, and the source region 77 is formed by introducing an n-type impurity. A description of subsequent manufacturing steps is omitted. The semiconductor device 1 is manufactured through the process including these steps mentioned above.

### [Effects of Semiconductor Device 1]

As described above, with this semiconductor device 1, the lower wiring structure consisting of the internal wiring portion 24 (wiring electrode 34) formed inside the semiconductor chip 2 and the upper wiring structure consisting of the extending wiring portion 25 that is electrically connected to the lower wiring structure and that is formed outside the semiconductor chip 2 (at the upper side higher than the first principal surface 3) are alternately continuous with each other along the first to fourth peripheral end surfaces 5A to 5D. Hence, the inspection wiring 23 has a chain structure in which a wiring structure exists with a constant cycle at the internal side of the semiconductor chip 2 and at the side opposite to the internal side with respect to the first principal surface 3.

For example, if a part of a cut edge surface of the semiconductor wafer 301, which has been cut by a dicing saw, is nicked, and, as a result, if chipping occurs, the inspection wiring 23 detects this chipping. Disadvantageously, for example, functional elements (in this preferred embodiment, the main transistor 8 and the control IC 9) of the semiconductor chip 2 might be broken if the thus generated chipping reaches element regions (in this preferred embodiment, the first element region 6 and the second element region 7) of the semiconductor chip 2. Therefore, an invalid area in which a functional element is not disposed is necessitated to be installed at a corner part of the semiconductor chip 2 at which chipping is particularly liable to occur with high frequency (for example, corner part 47, etc., of the first element region 6 of FIG. 1).

Therefore, the configuration of the present disclosure makes it possible to suppress chipping by means of the inspection wiring 23 before the chipping reaches an element region of the semiconductor chip 2. This inspection wiring 23 is an annular structural component that suppresses chipping, and may be referred to as a seal ring. In the inspection wiring 23, a resistance value changes when a part is nicked or broken because of contact with chipping (for example, when cracks and the like are made). Therefore, it is possible to easily examine the presence or absence of a chipping defect of the semiconductor chip 2 by inspecting a change in the resistance value before and after performing a dicing operation.

Additionally, the technique of visually inspecting the presence or absence of a chipping defect is performed on the basis of a human sense, and therefore there is a possibility that human errors will occur, and there is a case in which variations in the criteria of defective articles occur depending on testers. However, the inspection wiring 23 of the present disclosure determines the presence or absence of a defective article by means of a numerical value that is electrically detected, and therefore variations in the criteria of defective articles are small, and it is possible to detect a defective article efficiently and with high accuracy. Therefore, there is no need to set the corner part of the semiconductor chip 2 as an element invalid area, and it is possible to effectively utilize the corner part of the semiconductor chip 2 as an element area.

Additionally, the inspection wiring 23 has a chain structure in which a wiring structure exists with a constant cycle at the internal side of the semiconductor chip 2 and at the side opposite to the internal side with respect to the first principal surface 3. Therefore, it is possible to accurately detect chipping on both sides of the internal side of the semiconductor chip 2 and the side opposite to the internal side with respect to the first principal surface 3. Additionally, the first longitudinal wiring portion 40 (first connection via 201) and the second longitudinal wiring portion 42 (second connection via 202) are evenly provided along the peripheral end surfaces 5A to 5D of the semiconductor chip 2, and therefore, even when chipping comes into contact with a part of the interlayer insulating layer 17 between the first wiring layer 191 and the second wiring layer 192, it is possible to detect this chipping. In other words, the inspection wiring 23 having the chain structure is enabled to provide a more highly accurate chipping detection capability than in the configuration of Patent Literature 1 in which a contact plug is selectively formed only at an end portion of an inspection wiring.

Additionally, the internal wiring portion 24 is the trench wiring structure 31 consisting of a DTI structure, and therefore it is possible to form it through the same step as the trench separation structure 53 that divisionally forms the first element region 6. Therefore, a lesser number of steps relative to the formation of the inspection wiring 23 are performed.

### [Modification of Inspection Wiring 23]

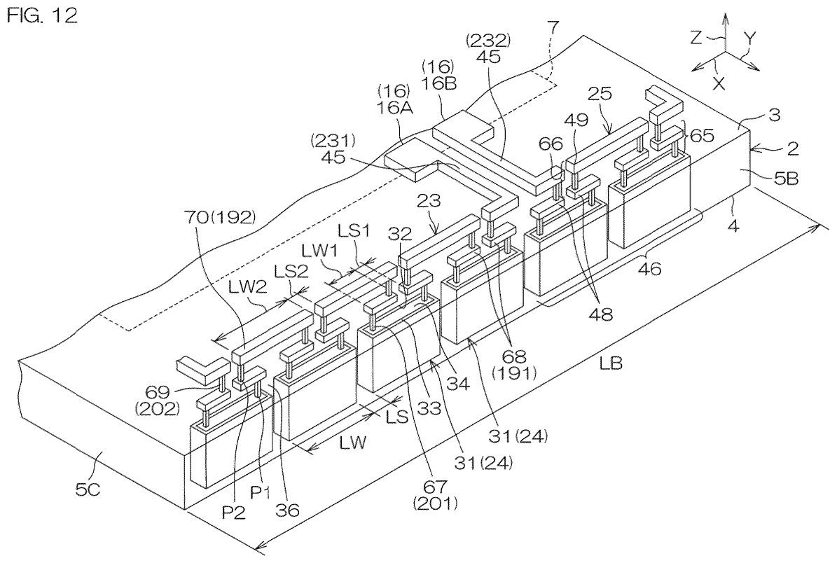

FIG. 12 to FIG. 19 are views shown to describe modifications of the inspection wiring 23 of FIG. 10. A plurality of modifications of the inspection wiring 23 are hereinafter mentioned, and yet the mode of the inspection wiring 23 is not limited to these modifications described below.

### (1) First Modification

Referring to FIG. 12, the extending wiring portion 25 may include a first stepped portion 65 that extends in a direction in which one of the pair of internal wiring portions 24 adjoining each other and the other internal wiring portion 24 recede from each other and a convex second stepped portion 66 that connects the forward end portions 39 of the first stepped portion 65.

In this modification, the first stepped portion 65 includes a first longitudinal wiring portion 67 and a first lateral wiring portion 68. The first longitudinal wiring portion 67 and the first lateral wiring portion 68 are formed by the first connection via 201 and the first wiring layer 191, respectively. A lower end portion of the first longitudinal wiring portion 67 is connected to an end portion of the internal wiring portion 24 (in this modification, end portion in the longitudinal direction of the wiring electrode 34). The connection position of the first longitudinal wiring portion 67 (first connection via 201) may be the first position P1 in a direction along the first to fourth peripheral end surfaces 5A to 5D.

The first lateral wiring portion 68 horizontally extends from an upper end portion of the first longitudinal wiring portion 67 in a direction in which the first lateral wiring portion 68 approaches a central portion of the internal wiring portion 24 so as to overlap with the internal wiring portion 24. For example, on the basis of the single internal wiring portion 24, the first lateral wiring portion 68 may be defined as an inward extension portion that extends toward the central portion of the internal wiring portion 24.

In this modification, the internal wiring length LW may be not less than 6.0 μm and not more than 12.0 μm. Preferably, the internal wiring length LW is not less than 8.0 μm and not more than 10.0 μm. Additionally, the length of the non-wiring region 36 (length of a space between the internal wiring portions 24) may be not less than 0.4 μm and not more than 1.2 μm. Preferably, the length LS is not less than 0.6 μm and not more than 1.0 μm.

The first wiring length LW1 of the first lateral wiring portion 68 may be 2.1 μm or more. Additionally, the sum of the first wiring lengths LW1 in each of the peripheral end surfaces 5A to 5D (total length LT1 of the first lateral wiring portion 68 (LW1×number of the first lateral wiring portions 68)) may be not less than 50% and not more than 75% with respect to the length of each of the peripheral end surfaces 5A to 5D (in FIG. 12, length LB of the second peripheral end surface 5B). Preferably, the total length LT1 is not less than 65% and not more than 75% with respect to the length LB.

Additionally, the length between the first lateral wiring portions 68 adjoining each other above the internal wiring portion 24 (length LS1 of a space between the first lateral wiring portions 68) may be 0.6 μm or more. Additionally, the sum of the lengths LS1 in each of the peripheral end surfaces 5A to 5D (total length LTS1) may be not less than 25% and not more than 50% with respect to the length of each of the peripheral end surfaces 5A to 5D (in FIG. 12, length LB of the second peripheral end surface 5B). Preferably, the total length LTS1 is not less than 25% and not more than 35% with respect to the length LB.

In this modification, the second stepped portion 66 includes a second longitudinal wiring portion 69 and a second lateral wiring portion 70. The second longitudinal wiring portion 69 and the second lateral wiring portion 70 are formed by the second connection via 202 and the second wiring layer 192, respectively. A lower end portion of the second longitudinal wiring portion 69 is connected to an end portion of the first lateral wiring portion 68 (forward end portion 48 of the first stepped portion 65). The connection position of the second longitudinal wiring portion 69 may be the second position P2 in the direction along the first to fourth peripheral end surfaces 5A to 5D. The second position P2 is a position differing from the first position P1. In other words, the second position P2 deviates with respect to the first position P1 in the normal direction Z of the first principal surface 3. Additionally, the first longitudinal wiring portion 67 is disposed at a position directly on the end portion in the longitudinal direction of the internal wiring portion 24, whereas the second longitudinal wiring portion 69 is disposed at a position directly on the central portion in the longitudinal direction of the internal wiring portion 24.

The second lateral wiring portion 70 connects the pair of first lateral wiring portions 68 that straddle the non-wiring region 36 and that are connected to the internal wiring portions 24 adjoining each other, respectively, and extends horizontally while maintaining a stacked relationship with the first lateral wiring portion 68. An end portion 49 in the longitudinal direction of the second lateral wiring portion 70 faces the forward end portion 39 of the first lateral wiring portion 68 in the normal direction Z of the first principal surface 3.

The second wiring length LW2 of the second lateral wiring portion 70 is longer than the length LS of the non-wiring region 36. The second wiring length LW2 may be 5.6 μm or more. Additionally, the sum of the second wiring lengths LW2 in each of the peripheral end surfaces 5A to 5D (total length LT2 of the second lateral wiring portion 70 (LW2×number of the second lateral wiring portions 70)) may be not less than 50% and not more than 75% with respect to the length of each of the peripheral end surfaces 5A to 5D (in FIG. 12, length LB of the second peripheral end surface 5B). Preferably, the total length LT2 is not less than 65% and not more than 75% with respect to the length LB.

Additionally, the length between the second lateral wiring portions 70 adjoining each other (length LS2 of a space between the second lateral wiring portions 70) may be 0.6 μm or more. Additionally, the sum of the lengths LS2 in each of the peripheral end surfaces 5A to 5D (total length LTS2) may be not less than 25% and not more than 50% with respect to the length of each of the peripheral end surfaces 5A to 5D (in FIG. 12, length LB of the second peripheral end surface 5B). Preferably, the total length LTS2 is not less than 25% and not more than 35% with respect to the length LB.

As described above, in this modification, the first lateral wiring portion 68 is formed so as to extend toward the inward side of the internal wiring portion 24, and does not jut out onto the non-wiring region 36. This makes it possible to effectively utilize the upper region of the internal wiring portion 24, and makes it possible to prevent the first lateral wiring portions 68 adjoining each other from interfering with each other in the upper region of the non-wiring region 36. Therefore, it is possible to lengthen the internal wiring length LW of the internal wiring portion 24 and the second wiring length LW2 of the second lateral wiring portion 70, and it is possible to increase the ratio of the internal wiring portion 24, the first lateral wiring portion 68, and the second lateral wiring portion 70. Particularly, the connection position of both the first longitudinal wiring portion 67 and the second longitudinal wiring portion 69 with the first lateral wiring portion 68 is set to be end portions opposite to each other, thus making it possible to divert a current path for detection between the first lateral wiring portion 68 and the second lateral wiring portion 70 to an upper position of the central portion of the internal wiring portion 24. As a result, it is possible to detect the presence or absence of chipping defects of the plurality of layers of the first and second wiring layers 191 and 192 in the upper region of the internal wiring portion 24. Therefore, it is possible to improve the detection accuracy of the presence or absence of the chipping defects.

### (2) Second Modification

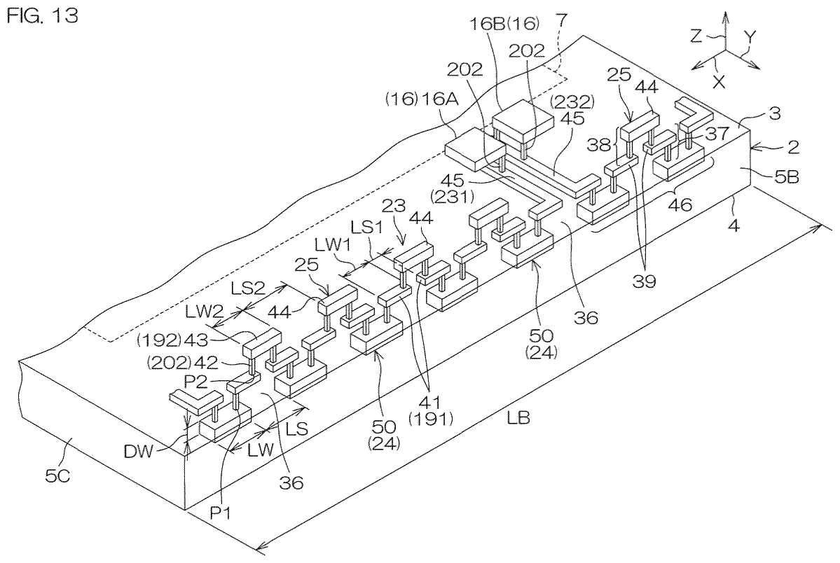

Referring to FIG. 13, the internal wiring portion 24 may be an impurity diffusion layer 50. In this modification, the impurity diffusion layer 50 is a p-type impurity diffusion layer that contains a p-type impurity introduced into the surficial portion of the first principal surface 3 of the semiconductor chip 2. The wiring depth DW of the impurity diffusion layer 50 is shallower than the trench wiring structure 31, and may be, for example, not less than 0.5 μm and not more than 4 μm. Preferably, the wiring depth DW of the impurity diffusion layer 50 is not less than 1 μm and not more than 3 μm.

Additionally, the impurity concentration of the impurity diffusion layer 50 may be the same as the p-type impurity concentration of the body region 58. For example, the impurity concentration of the impurity diffusion layer 50 may be not less than 1×10¹⁶ cm⁻³ and not more than 1×10¹⁸ cm⁻³. Therefore, it is possible to form the impurity diffusion layer 50 in the same step as the body region 58. Therefore, a lesser number of steps relative to the formation of the inspection wiring 23 are performed.

As described above, according to this modification, it is possible to provide the inspection wiring 23 by means of the impurity diffusion layer 50 (internal wiring portion 24) and the extending wiring portion 25, and therefore it is possible to easily inspect the presence or absence of a chipping defect of the semiconductor chip 2.

### (3) Third Modification

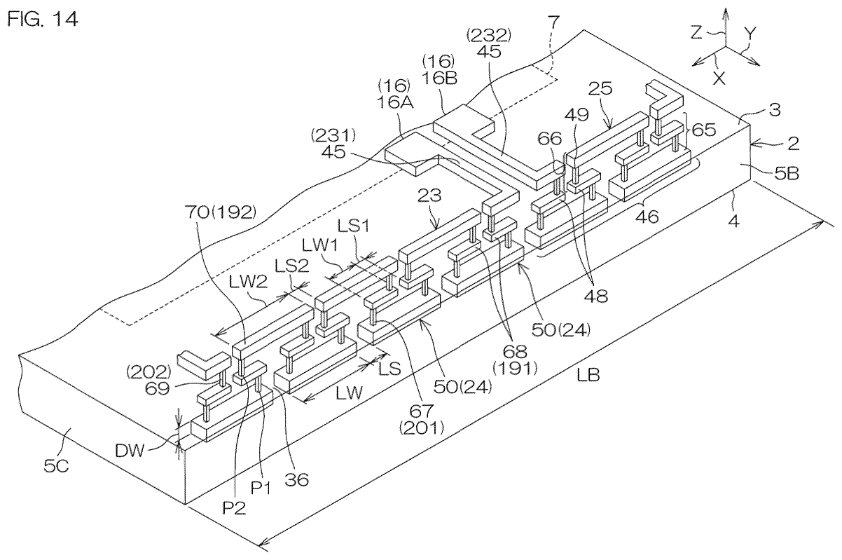

In this modification, referring to FIG. 14, the impurity diffusion layer 50 is formed instead of the trench wiring structure 31 of FIG. 12.

### (4) Fourth Modification

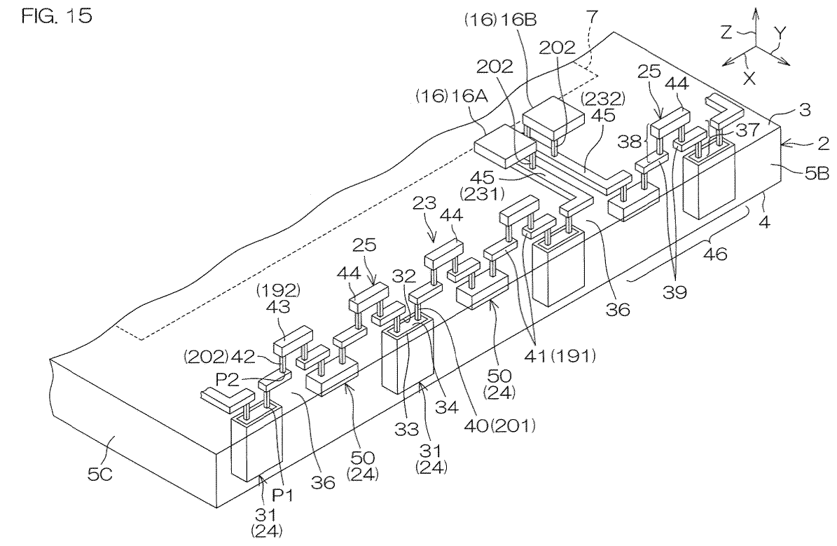

In this modification, referring to FIG. 15, the trench wiring structure 31 of FIG. 10 and the impurity diffusion layer 50 of FIG. 13 are alternately arrayed along the first to fourth peripheral end surfaces 5A to 5D of the semiconductor chip 2.

### (5) Fifth Modification

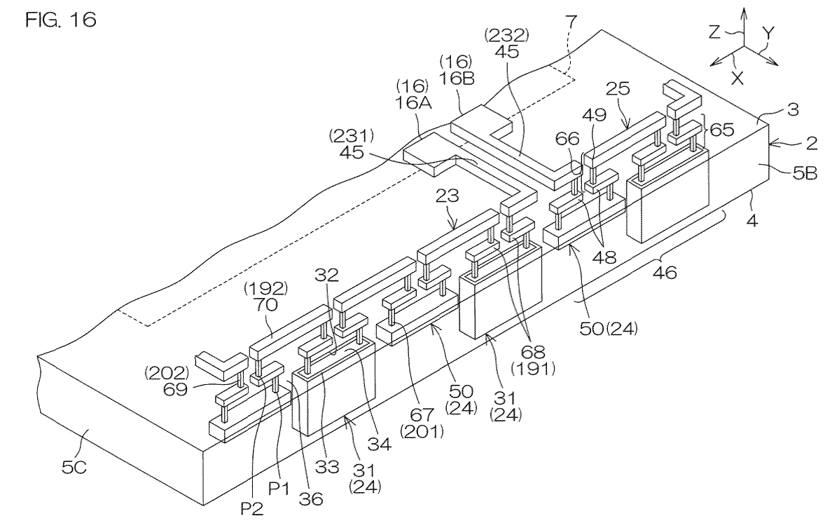

In this modification, referring to FIG. 16, the trench wiring structure 31 of FIG. 12 and the impurity diffusion layer 50 of FIG. 14 are alternately arrayed along the first to fourth peripheral end surfaces 5A to 5D of the semiconductor chip 2.

### (6) Sixth Modification

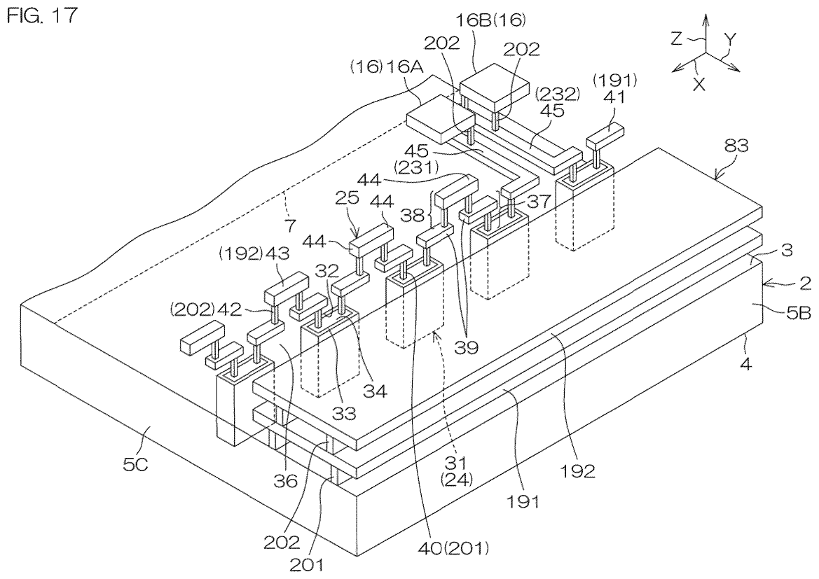

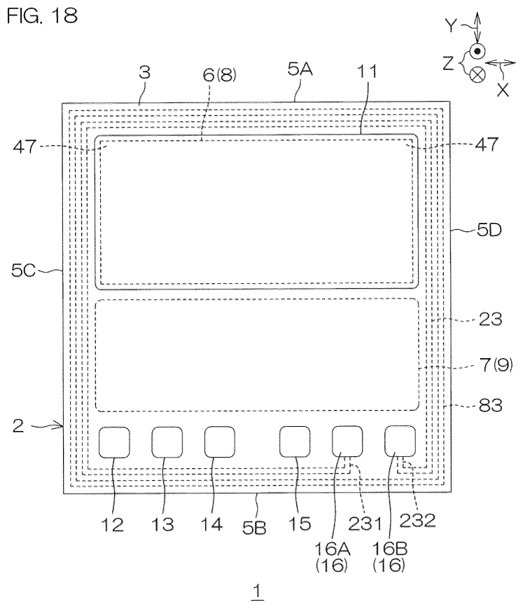

In this modification, referring to FIG. 17 and FIG. 18, a second inspection wiring 83 is additionally formed. The second inspection wiring 83 is an annular wiring layer formed along the first to fourth peripheral end surfaces 5A to 5D on the first principal surface 3 of the semiconductor chip 2. In this modification, the second inspection wiring 83 is physically and electrically away from the inspection wiring 23. The second inspection wiring 83 is formed between the inspection wiring 23 and the first to fourth peripheral end surfaces 5A to 5D, and surrounds the inspection wiring 23. In this preferred embodiment, the second inspection wiring 83 may be a multilayer wiring structure including the first connection via 201, the first wiring layer 191, the second connection via 202, and the second wiring layer 192.

As described above, according to this modification, when chipping occurs, it is possible to first suppress the chipping by means of the second inspection wiring 83 as a first stage. Even if the chipping exceeds the second inspection wiring 83, it is possible to detect the chipping by the inspection wiring 23 as a second stage. Therefore, even if the second inspection wiring 83 is broken by the chipping, it is possible to ship a product as a non-defective article if the presence or absence of the chipping is not detected by the inspection wiring 23. Hence, it is also possible to inspect the presence or absence of a chipping defect of the semiconductor chip 2 more accurately, and it is also possible to improve yields.

### (7) Seventh Modification

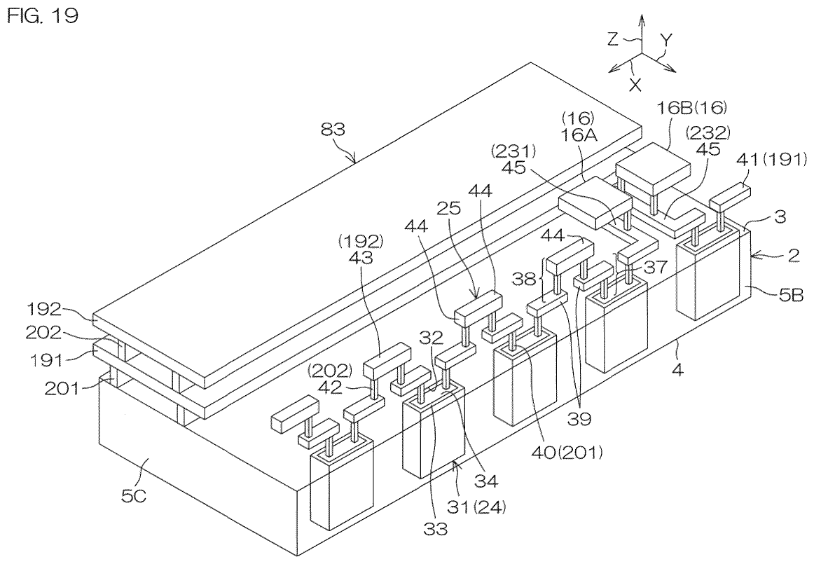

In this modification, referring to FIG. 19, the inspection wiring 23 is formed between the second inspection wiring 83 and the first to fourth peripheral end surfaces 5A to 5D, and surrounds the second inspection wiring 83.

As described above, according to this modification, the inspection wiring 23 is disposed outside the second inspection wiring 83, and therefore, even if a little chipping occurs, it is possible to detect the presence or absence of the chipping. Additionally, even if the false detection of the inspection wiring 23 occurs, it is possible to confirm the presence or absence of a chipping defect by visually inspecting the broken condition of the second inspection wiring 83. Therefore, it is possible to tighten the criteria of a defective article caused by chipping.

Although the preferred embodiments of the present disclosure have been described, the present disclosure can be embodied in other modes.

As described above, the preferred embodiments of the present disclosure are illustrative in all respects, and should not be construed limitedly, and are intended to include changes in all respects.

Features appended below can be extracted from this description and from the drawings.

### Appendix 1-1

A semiconductor device (1) comprising:
a semiconductor chip (2) that has a first principal surface (3) in which an element region (6, 7) is formed and a peripheral end surface (5A, 5B, 5C, 5D) surrounding the first principal surface (3); and
an inspection wiring (23) that is formed along the peripheral end surface (5A, 5B, 5C, 5D) on a side of the first principal surface (3) of the semiconductor chip (2) and that surrounds the element region (6, 7),
wherein the inspection wiring (23) includes a plurality of internal wiring portions (24) that are formed at a surficial portion of the first principal surface (3) of the semiconductor chip (2) and that are arrayed at a distance from each other along the peripheral end surface (5A, 5B, 5C, 5D) of the semiconductor chip (2) and an extending wiring portion (25) that is formed on the first principal surface (3) of the semiconductor chip (2) and that is provided between the internal wiring portions (24) adjoining each other, and wherein the internal wiring portion (24) and the extending wiring portion (25) are alternately arrayed along the peripheral end surface (5A, 5B, 5C, 5D).

### Appendix 1-2

The semiconductor device (1) according to Appendix 1-1, further comprising an insulating layer (17) formed at the first main surface (3) of the semiconductor chip (2),
wherein the extending wiring portion (25) includes a wiring layer (19) that is embedded in the insulating layer (17) at a distance from the first principal surface (3) in a thickness direction of the semiconductor chip (2) and that extends along the first principal surface (3) and a connection via (20) that extends from the wiring layer (19) in the thickness direction of the semiconductor chip (2) and that electrically connects the wiring layer (19) and the internal wiring portion (24).

### Appendix 1-3

The semiconductor device (1) according to Appendix 1-2, wherein the insulating layer (17) has a laminated structure including a first insulating layer (171) and a second insulating layer (172) placed on the first insulating layer (171), and
the wiring layer (19) includes a plurality of first wiring layers (191) that are formed on the first insulating layer (171) and that are separated from each other and a second wiring layer (192) that is formed on the second insulating layer (172) and that straddles the first wiring layers (191), and
the connection via (20) includes a first connection via (201) that connects the first wiring layer (191) and the internal wiring portion (24) and a second connection via (202) that connects the second wiring layer (192) and the first wiring layer (191).

### Appendix 1-4

The semiconductor device (1) according to Appendix 1-3, wherein the first wiring layer (191) includes an outward extension portion that extends toward an outside of the internal wiring portion (24) and that overlaps with a non-wiring region (36) interposed between the internal wiring portions (24) adjoining each other, and
the second wiring layer (192) includes a second wiring layer (192) that is formed so as to be installed within an interval of the non-wiring region (36) and so as to straddle the outward extension portions of the first wiring layers (191) adjoining each other.

### Appendix 1-5

The semiconductor device (1) according to Appendix 1-4, wherein the second wiring layer (192) is shorter than a length of the non-wiring region (36).

### Appendix 1-6

The semiconductor device (1) according to Appendix 1-3, wherein the first wiring layer (191) includes an inward extension portion that extends toward a central portion of the internal wiring portion (24), and
the second wiring layer (192) includes a second wiring layer (192) that extends along the inward extension portion while maintaining a stacked relationship with the inward extension portion and that is formed so as to straddle the inward extension portions of the first wiring layers (191) adjoining each other.

### Appendix 1-7

The semiconductor device (1) according to Appendix 1-6, wherein the second wiring layer (192) is longer than the non-wiring region (36).

### Appendix 1-8

The semiconductor device (1) according to any one of Appendix 1-3 to Appendix 1-7, wherein the first connection via (201) is disposed at a first position (P1) in a direction along the peripheral end surface (5A, 5B, 5C, 5D), and the second connection via (202) is disposed at a second position (P2) differing from the first position (P1) in the direction along the peripheral end surface (5A, 5B, 5C, 5D).

### Appendix 1-9

The semiconductor device (1) according to any one of Appendix 1-3 to Appendix 1-8, wherein the internal wiring portion (24) has a total length of not less than 50% and not more than 75% with respect to a length along a circumferential direction of the peripheral end surface (5A, 5B, 5C, 5D).

### Appendix 1-10

The semiconductor device (1) according to any one of Appendix 1-3 to Appendix 1-9, wherein the first wiring layer (191) has a total length of not less than 50% and not more than 75% with respect to the length along the circumferential direction of the peripheral end surface (5A, 5B, 5C, 5D).

### Appendix 1-11

The semiconductor device (1) according to any one of Appendix 1-3 to Appendix 1-10, wherein the second wiring layer (192) has a total length of not less than 50% and not more than 75% with respect to the length along the circumferential direction of the peripheral end surface (5A, 5B, 5C, 5D).

### Appendix 1-12

The semiconductor device (1) according to any one of Appendix 1-1 to Appendix 1-11, wherein the internal wiring portion (24) includes a trench wiring structure (31) that includes a wiring trench (32) formed in the semiconductor chip (2), a wiring insulating layer (33) formed on an inner surface of the wiring trench (32), and a wiring conductive layer (34) embedded in the wiring trench (32) with the wiring insulating layer (33) between the wiring conductive layer (34) and the wiring trench (32).

### Appendix 1-13

The semiconductor device (1) according to Appendix 1-12, further comprising a region separation structure (53) that is formed at the surficial portion of the first principal surface (3) of the semiconductor chip (2) and that divisionally forms the element region (6, 7),
wherein the region separation structure (53) includes a trench separation structure (53) that includes a separation trench (54) formed in the semiconductor chip (2), a separation insulating layer (55) formed on an inner surface of the separation trench (54), and a separation conductive layer (56) embedded in the separation trench (54) with the separation insulating layer (55) between the separation conductive layer (56) and the separation trench (54).

### Appendix 1-14

The semiconductor device (1) according to Appendix 1-13, wherein the wiring trench (32) and the separation trench (54) are mutually same in depth.

### Appendix 1-15

The semiconductor device (1) according to any one of Appendix 1-1 to Appendix 1-14, wherein the internal wiring portion (24) includes an impurity diffusion layer (50) that contains an impurity introduced into the surficial portion of the first principal surface (3) of the semiconductor chip (2).

### Appendix 1-16

The semiconductor device (1) according to Appendix 1-15 citing any one of Appendix 1-12 to Appendix 1-14, wherein the trench wiring structure (31) and the impurity diffusion layer (50) are alternately arrayed along the peripheral end surface (5A, 5B, 5C, 5D) of the semiconductor chip (2).

### Appendix 1-17

The semiconductor device (1) according to any one of Appendix 1-1 to Appendix 1-16, further comprising a second inspection wiring (83) that is formed along the peripheral end surface (5A, 5B, 5C, 5D) on the first principal surface (3) of the semiconductor chip (2), that includes an annular wiring layer (19) surrounding the element region (6, 7), and that is physically and electrically away from the inspection wiring (23).

### Appendix 1-18

The semiconductor device (1) according to Appendix 1-17, wherein the second inspection wiring (83) is formed between the inspection wiring (23) and the peripheral end surface (5A, 5B, 5C, 5D), and surrounds the inspection wiring (23).

### Appendix 1-19

The semiconductor device (1) according to Appendix 1-17, wherein the inspection wiring (23) is formed between the second inspection wiring (83) and the peripheral end surface (5A, 5B, 5C, 5D), and surrounds the second inspection wiring (83).

### Appendix 1-20

The semiconductor device (1) according to any one of Appendix 1-1 to Appendix 1-19, further comprising:
a pad terminal (16) formed on the first principal surface (3) of the semiconductor chip (2); and
a circuit wiring (45) that electrically connects the pad terminal (16) and the inspection wiring (23).

### Appendix 2-1

A semiconductor device (1) comprising:
a semiconductor chip (2) that has a first principal surface (3) in which an element region (6, 7) is formed and a peripheral end surface (5A, 5B, 5C, 5D) surrounding the first principal surface (3); and
an inspection wiring (23) that is formed along the peripheral end surface (5A, 5B, 5C, 5D) on a side of the first principal surface (3) of the semiconductor chip (2) and that surrounds the element region (6, 7),
wherein the inspection wiring (23) has a configuration in which a lower wiring structure (24) formed inside the semiconductor chip (2) and an upper wiring structure (25) that is electrically connected to the lower wiring structure (24) and that is formed on an upper side that is higher than the first principal surface (3) of the semiconductor chip (2) are alternately continuous with each other along the peripheral end surface (5A, 5B, 5C, 5D).

### Appendix 3-1

A semiconductor device (1) comprising:
a semiconductor chip (2) that has a first principal surface (3) in which an element region (6, 7) is formed and a peripheral end surface (5A, 5B, 5C, 5D) surrounding the first principal surface (3); and
an inspection wiring (23) that is formed along the peripheral end surface (5A, 5B, 5C, 5D) on a side of the first principal surface (3) of the semiconductor chip (2) and that surrounds the element region (6, 7),
wherein the inspection wiring (23) has a chain structure in which a wiring structure exists with a constant cycle at an internal side of the semiconductor chip (2) and at a side opposite to the internal side with respect to the first principal surface (3).

What is claimed is:

1. A semiconductor device comprising:
a semiconductor chip that has a first principal surface in which an element region is formed and a peripheral end surface surrounding the first principal surface; and
an inspection wiring that is formed along the peripheral end surface on a side of the first principal surface of the semiconductor chip and that surrounds the element region,
wherein the inspection wiring includes a plurality of internal wiring portions that are formed at a surficial portion of the first principal surface of the semiconductor chip and that are arrayed at a distance from each other along the peripheral end surface of the semiconductor chip and a extending wiring portion that is formed on the first principal surface of the semiconductor chip and that is provided between the internal wiring portions adjoining each other, and wherein the internal wiring portion and the extending wiring portion are alternately arrayed along the peripheral end surface.

2. The semiconductor device according to claim 1, further comprising an insulating layer formed at the first main surface of the semiconductor chip,
wherein the extending wiring portion includes a wiring layer that is embedded in the insulating layer at a distance from the first principal surface in a thickness direction of the semiconductor chip and that extends along the first principal surface and a connection via that extends from the wiring layer in the thickness direction of the semiconductor chip and that electrically connects the wiring layer and the internal wiring portion.

3. The semiconductor device according to claim 2, wherein the insulating layer has a laminated structure including a first insulating layer and a second insulating layer placed on the first insulating layer, and
the wiring layer includes a plurality of first wiring layers that are formed on the first insulating layer and that are separated from each other and a second wiring layer that is formed on the second insulating layer and that straddles the first wiring layers, and
the connection via includes a first connection via that connects the first wiring layer and the internal wiring portion and a second connection via that connects the second wiring layer and the first wiring layer.

4. The semiconductor device according to claim 3, wherein the first wiring layer includes an outward extension portion that extends toward an outside of the internal wiring portion and that overlaps with a non-wiring region interposed between the internal wiring portions adjoining each other, and
the second wiring layer includes a second wiring layer that is formed so as to be installed within an interval of the non-wiring region and so as to straddle the outward extension portions of the first wiring layers adjoining each other.

5. The semiconductor device according to claim 4, wherein the second wiring layer is shorter than a length of the non-wiring region.

6. The semiconductor device according to claim 3, wherein the first wiring layer includes an inward extension portion that extends toward a central portion of the internal wiring portion, and
the second wiring layer includes a second wiring layer that extends along the inward extension portion while maintaining a stacked relationship with the inward extension portion and that is formed so as to straddle the inward extension portions of the first wiring layers adjoining each other.

7. The semiconductor device according to claim 6, wherein the second wiring layer is longer than the non-wiring region.

8. The semiconductor device according to claim 3, wherein the first connection via is disposed at a first position in a direction along the peripheral end surface, and the second connection via is disposed at a second position differing from the first position in the direction along the peripheral end surface.

9. The semiconductor device according to claim 3, wherein the internal wiring portion has a total length of not less than 50% and not more than 75% with respect to a length along a circumferential direction of the peripheral end surface.

10. The semiconductor device according to claim 3, wherein the first wiring layer has a total length of not less than 50% and not more than 75% with respect to the length along the circumferential direction of the peripheral end surface.

11. The semiconductor device according to claim 3, wherein the second wiring layer has a total length of not less than 50% and not more than 75% with respect to the length along the circumferential direction of the peripheral end surface.

12. The semiconductor device according to claim 1, wherein the internal wiring portion includes a trench wiring structure that includes a wiring trench formed in the semiconductor chip, a wiring insulating layer formed on an inner surface of the wiring trench, and a wiring conductive layer embedded in the wiring trench with the wiring insulating layer between the wiring conductive layer and the wiring trench.

13. The semiconductor device according to claim 12, further comprising a region separation structure that is formed at the surficial portion of the first principal surface of the semiconductor chip and that divisionally forms the element region,
wherein the region separation structure includes a trench separation structure that includes a separation trench formed in the semiconductor chip, a separation insulating layer formed on an inner surface of the separation trench, and a separation conductive layer embedded in the separation trench with the separation insulating layer between the separation conductive layer and the separation trench.

14. The semiconductor device according to claim 13, wherein the wiring trench and the separation trench are mutually same in depth.

15. The semiconductor device according to claim 1, wherein the internal wiring portion includes an impurity diffusion layer that contains an impurity introduced into the surficial portion of the first principal surface of the semiconductor chip.

16. The semiconductor device according to claim 15, wherein the trench wiring structure and the impurity diffusion layer are alternately arrayed along the peripheral end surface of the semiconductor chip.

17. The semiconductor device according to claim 1, further comprising a second inspection wiring that is formed along the peripheral end surface on the first principal surface of the semiconductor chip, that includes an annular wiring layer surrounding the element region, and that is physically and electrically away from the inspection wiring.

18. The semiconductor device according to claim 17, wherein the second inspection wiring is formed between the inspection wiring and the peripheral end surface, and surrounds the inspection wiring.

19. The semiconductor device according to claim 17, wherein the inspection wiring is formed between the second inspection wiring and the peripheral end surface, and surrounds the second inspection wiring.

20. The semiconductor device according to claim 1 further comprising:
a pad terminal formed on the first principal surface of the semiconductor chip; and
a circuit wiring that electrically connects the pad terminal and the inspection wiring.
